(19) United States
(12) Patent Application Publication
(10) Pub. No.: US 2025/0116906 A1
(43) Pub. Date: Apr. 10, 2025

(54) TRANSISTOR AND MANUFACTURING METHOD FOR TRANSISTOR

(71) Applicant: Sharp Display Technology Corporation, Kameyama City (JP)

(72) Inventors: Tadayoshi MIYAMOTO, Kameyama City (JP); Yoshinobu NAKAMURA, Kameyama City (JP); Toshihiro KANEKO, Kameyama City (JP); Sohtaroh TANAKA, Kameyama City (JP)

(21) Appl. No.: 18/883,192

(22) Filed: Sep. 12, 2024

(30) Foreign Application Priority Data
Oct. 6, 2023 (JP) 2023-174163

(51) Int. Cl. G02F 1/1368; G02F 1/1333; H01L 27/12; H01L 29/786

(52) U.S. Cl. CPC G02F 1/1368; G02F 1/13338; H10D 30/6723; H10D 30/6731; H10D 30/6745; H10D 86/0221; H10D 86/0231; H10D 86/421; H10D 86/451; H10D 86/60

(57) ABSTRACT

A transistor includes a semiconductor portion extending in a first direction, a first electrode extending in a second direction intersecting the first direction and is disposed overlapping a portion of the semiconductor portion, a first insulating film that is interposed between the first electrode and the semiconductor portion, a second electrode that is connected to the semiconductor portion, and a third electrode that is connected to the semiconductor portion, in which the first insulating film includes a first thick portion and a second thick portion having a film thickness greater than that of the first thick portion, at least two of the first thick portions are disposed at intervals in the second direction at positions overlapping both the first electrode and the semiconductor portion, and the second thick portion is disposed to be interposed between the two first thick portions in the second direction at a position overlapping both the first electrode and the semiconductor portion.

### CROSS-REFERENCE TO RELATED APPLICATIONS

This application claims the benefit of priority to Japanese Patent Application Number 2023-174163 filed on Oct. 6, 2023. The entire contents of the above-identified application are hereby incorporated by reference.

### BACKGROUND

### Technical Field

The technology described in the present specification relates to a transistor and a manufacturing method for the transistor.

In the related art, an example of a transistor is known, as described in JP 2000-332253 A. The transistor disclosed in JP 2000-332253 A includes a semiconductor film constituted of a polysilicon film that constitutes an active layer of a TFT, and the semiconductor film has a plurality of high-concentration source/drain regions formed at predetermined intervals in a channel width direction. All of the high-concentration source/drain regions are formed at positions shifted in a channel length direction when viewed from an end of a gate electrode. A plurality of contact holes are formed corresponding to the respective high-concentration source/drain regions. In the semiconductor film, a portion facing the end of the gate electrode and portions between adjacent high-concentration source/drain regions in the channel width direction are low-concentration regions.

### SUMMARY

JP 2000-332253 A discloses a structure in which a semiconductor film is divided into a plurality of small island regions arranged in parallel at predetermined intervals in the channel width direction. With this structure, it is unlikely that grain boundaries will concentrate in some of the small island regions, and thus it is possible to prevent concentration of source-drain current caused by uneven distribution of grain boundaries. However, when the semiconductor film is divided into the plurality of small island regions, each small island region has an outer peripheral end, and thus the sum of the lengths of the outer peripheral ends in the plurality of small island regions is greater than the length of the outer peripheral end of the semiconductor film when the semiconductor film has a single structure. For this reason, there is a high possibility that localized protrusions caused by minute pieces of foreign matter will occur at the outer peripheral ends of the plurality of small island regions, or that minute foreign matter will remain and become protrusions. When such protrusions occur at the outer peripheral ends of the small island regions, a locally thin film portion will occur in a gate insulating film formed on an upper layer side, causing problems such as a deterioration in voltage resistance performance due to the thin film portion or an increased susceptibility to leakage. As a result, there is a concern of a decrease in yield.

The technology described in this specification has been contrived in view of the above circumstances, and an object thereof is to improve a yield.

(1) A transistor according to the technology described in this specification includes a semiconductor portion extending in a first direction, the semiconductor portion being made of a semiconductor material, a first electrode extending in a second direction intersecting the first direction, the first electrode being disposed overlapping a portion of the semiconductor portion, a first insulating film interposed between the first electrode and the semiconductor portion, a second electrode disposed overlapping a portion of the semiconductor portion, the second electrode being connected to the semiconductor portion, and a third electrode disposed overlapping a portion of the semiconductor portion at a position spaced apart from a connection position between the second electrode and the semiconductor portion in the first direction, the third electrode being connected to the semiconductor portion, in which the first insulating film includes a first thick portion and a second thick portion having a film thickness greater than a thickness of the first thick portion, at least two of the first thick portions are disposed at intervals in the second direction at positions overlapping both the first electrode and the semiconductor portion, and the second thick portion is disposed to be interposed between the two first thick portions in the second direction at a position overlapping both the first electrode and the semiconductor portion.

(2) In addition to (1) described above, in the transistor, the first insulating film may have a layered structure of a lower insulating film disposed on an upper layer side of the semiconductor portion and an upper insulating film disposed on an upper layer side of the lower insulating film and made of a material different from a material of the lower insulating film.

(3) In addition to (2) described above, in the transistor, the first thick portion may be constituted of the lower insulating film, and the second thick portion may be constituted of the upper insulating film and the lower insulating film.

(4) In addition to (1) described above, in the transistor, the first insulating film may have a single-layer structure.

(5) In addition to any one of (1) to (4) described above, in the transistor, the first insulating film may include a third thick portion having a film thickness greater than a thickness of the first thick portion, and the third thick portion may be disposed overlapping an outer peripheral end of the semiconductor portion.

(6) In addition to (5) described above, in the transistor, the third thick portion may have the same film thickness as that of the second thick portion.

(7) In addition to any one of (1) to (6) described above, in the transistor, at least three of the first thick portions may be disposed at intervals in the second direction, at least two second thick portions may be disposed at intervals in the second direction, and among the at least three first thick portions, the first thick portion located at other than both ends in the second direction may have a dimension in the second direction which is smaller than a dimension of the two first thick portions located at the both ends in the second direction.

(8) In addition to any of (1) to (7) described above, in the transistor, at least three of the first thick portions may be disposed at intervals in the second direction, at least two of the second thick portions may be disposed at intervals in the second direction, the first electrode may include a first overlapping portion that overlaps the first thick portion located at other than both ends in the second direction among the at least three of the first thick portions, and two second overlapping portions that overlap the two first thick portions located at the both ends in the second direction among the at least three of the first thick portions, and the first overlapping portion may have a dimension which is larger in the first direction than a dimension of the second overlapping portion.

(9) A manufacturing method for a transistor according to the technology described in this specification includes forming a semiconductor film made of a semiconductor material, forming a first resist film made of a photosensitive material on an upper layer side of the semiconductor film, exposing and developing the first resist film, providing a semiconductor portion extending in a first direction by etching the semiconductor film using the first resist film as a mask, forming a first insulating film on an upper layer side of the semiconductor portion, forming a second resist film made of a photosensitive material on an upper layer side of the first insulating film, exposing and developing the second resist film, etching the first insulating film using the second resist film as a mask to provide at least two first thick portions disposed at intervals in a second direction intersecting the first direction so as to overlap the semiconductor portion, and a second thick portion that is disposed to be interposed between the two first thick portions in the second direction at positions overlapping the semiconductor portion and has a film thickness greater than a thickness of the first thick portion, forming a first conductive film on an upper layer side of the first insulating film and patterning the first conductive film to provide a first electrode that extends in the second direction, overlaps a portion of the semiconductor portion, and is disposed to overlap the at least two first thick portions and the second thick portion, and forming a second conductive film on an upper layer side of the first electrode and patterning the second conductive film to provide a second electrode that is disposed to overlap a portion of the semiconductor portion and is connected to the semiconductor portion, and a third electrode that is disposed to overlap a portion of the semiconductor portion at a position spaced apart from a connection position between the second electrode and the semiconductor portion in the first direction and is connected to the semiconductor portion.

(10) In addition to (9) described above, the manufacturing method for the transistor, may further comprise: forming the first resist film made of a negative photosensitive material on the upper layer side of the semiconductor film, exposing the first resist film through a photomask and then developing the first resist film, the photomask having a light shielding region disposed not to overlap a formation area for the semiconductor portion to be formed to block light, at least two transmissive regions disposed at intervals in the second direction so as to overlap the formation area for the semiconductor portion to be formed and transmitting light, and a semi-transmissive region overlapping the formation area for the semiconductor portion to be formed, disposed to be interposed between the at least two transmissive regions in the second direction, and having a light transmittance higher than a light transmittance of the light shielding region and lower than light transmittance of the transmissive region, forming the second resist film made of a positive photosensitive material on the upper layer side of the first insulating film, and exposing the second resist film through the photomask and then developing the second resist film.

According to the technology described in this specification, it is possible to improve a yield.

### BRIEF DESCRIPTION OF DRAWINGS

The disclosure will be described with reference to the accompanying drawings, wherein like numbers reference like elements.

FIG. 1 is a plan view of a liquid crystal panel, a driver, a flexible substrate, and the like that constitute a liquid crystal display device according to a first embodiment.

FIG. 2 is a cross-sectional view of the liquid crystal panel, the driver, the flexible substrate, and the like according to the first embodiment.

FIG. 3 is a circuit diagram showing an electrical configuration of an array substrate that constitutes the liquid crystal panel according to the first embodiment.

FIG. 4 is a cross-sectional view of a first TFT and a second TFT provided on the array substrate according to the first embodiment.

FIG. 5 is a plan view of the first TFT according to the first embodiment.

FIG. 6 is a cross-sectional view of the first TFT according to the first embodiment which is taken along a line vi-vi in FIG. 5.

FIG. 7 is a cross-sectional view similar to FIG. 6, showing a state where a first resist film is formed in a third step included in an array substrate manufacturing step according to the first embodiment.

FIG. 8 is a cross-sectional view similar to FIG. 6, showing a state where the first resist film is exposed through a photomask in the third step included in the array substrate manufacturing step according to the first embodiment.

FIG. 9 is a cross-sectional view similar to FIG. 6, showing a state where the first resist film is developed in the third step included in the array substrate manufacturing step according to the first embodiment.

FIG. 10 is a cross-sectional view similar to FIG. 6, showing a state where the first resist film is removed in the third step included in the array substrate manufacturing step according to the first embodiment.

FIG. 11 is a cross-sectional view similar to FIG. 6, showing a state where a lower insulating film, an upper insulating film, and a second resist film are formed in a fourth step included in the array substrate manufacturing step according to the first embodiment.

FIG. 12 is a cross-sectional view similar to FIG. 6, showing a state where a second resist film is exposed through a photomask in the fourth step included in the array substrate manufacturing step according to the first embodiment.

FIG. 13 is a cross-sectional view similar to FIG. 6, showing a state where the second resist film is developed in the fourth step included in the array substrate manufacturing step according to the first embodiment.

FIG. 14 is a cross-sectional view similar to FIG. 6, showing a state where the upper insulating film is etched through the second resist film in the fourth step included in the array substrate manufacturing step according to the first embodiment.

FIG. 15 is a cross-sectional view similar to FIG. 6, showing a state where the second resist film is removed in the fourth step included in the array substrate manufacturing step according to the first embodiment.

FIG. 16 is a cross-sectional view similar to FIG. 6, showing a first TFT according to a second embodiment.

FIG. 17 is a plan view of a first TFT according to a third embodiment.

FIG. 18 is a cross-sectional view of the first TFT according to the third embodiment which is taken along a line xviii-xviii in FIG. 17.

FIG. 19 is a plan view of a first TFT according to a fourth embodiment.

### DESCRIPTION OF EMBODIMENTS

### First Embodiment

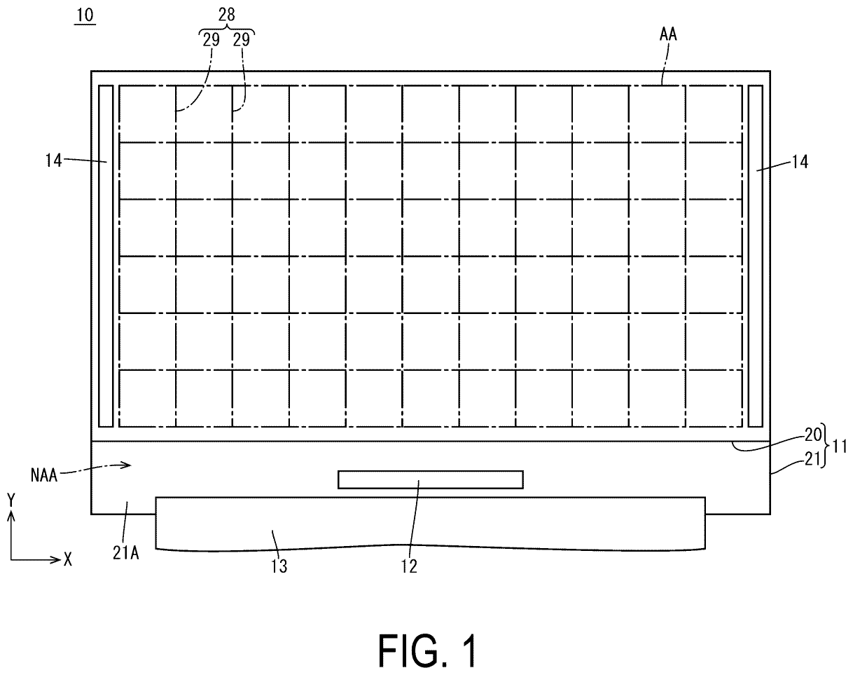

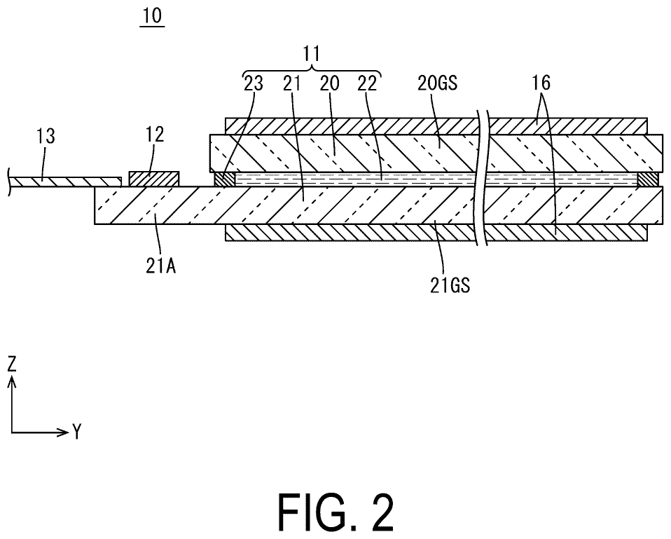

A first embodiment will be described with reference to FIG. 1 to FIG. 15. In this embodiment, a liquid crystal display device 10 having a display function and a touch panel function (position input function) will be described. Some drawings show an X-axis, a Y-axis, and a Z-axis, and axial directions are drawn to be directions shown in the drawings. In addition, upper sides in FIGS. 2, 4, and 6 to 15 are assumed to be front sides, and lower sides in the drawings are assumed to be back sides.

The liquid crystal display device 10, as shown in FIG. 1, includes at least the liquid crystal panel (display device, display panel) 11 that has a horizontally elongated rectangular shape and is capable of displaying an image, and a backlight device (illumination device), which is an external light source configured to irradiate the liquid crystal panel 11 with light to be used for display. The backlight device includes a light source (for example, an LED or the like) disposed on the back side (back face side) of the liquid crystal panel 11 and configured to emit light of a white color (white light), an optical member configured to impart an optical effect on the light from the light source, thereby converting the light into planar light, and the like. A center-side portion of a screen of the liquid crystal panel 11 is a display region AA in which an image is displayed. On the other hand, a frame-shaped outer peripheral portion surrounding the display region AA in the screen of the liquid crystal panel 11 is a non-display region NAA in which images are not displayed.

As shown in FIG. 1, a circuit portion (peripheral circuit portion) 14 is provided in the non-display region NAA of the liquid crystal panel 11. A pair of circuit portions 14 are disposed to sandwich the display region AA from both sides thereof in the X-axis direction. The circuit portions 14 are provided in a belt-shaped range extending in the Y-axis direction. The circuit portions 14 are configured to supply a scanning signal to a gate wiring line 26 to be described later, and are monolithically provided on an array substrate 21 to be described later. The circuit portion 14 is a gate driver monolithic (GDM) circuit. The circuit portion 14 includes a shift register circuit configured to output a scanning signal at a predetermined timing, a buffer circuit for amplifying the scanning signal, and the like. The circuit portion 14 is provided with various circuit elements including at least a first transistor (TFT) 15. A detailed configuration of the first TFT 15 will be described later.

The liquid crystal panel 11 will be described in detail with reference to FIG. 2 in addition to FIG. 1. As shown in FIGS. 1 and 2, the liquid crystal panel 11 is formed by bonding a pair of substrates 20 and 21 together. Out of the pair of substrates 20 and 21, the front side (front face side) is a counter substrate (CF substrate, second substrate) 20, and the back side (back face side) is an array substrate (first substrate) 21. Both the counter substrate 20 and the array substrate 21 are formed by layering various films on inner face sides of glass substrates 20GS and 21GS. A liquid crystal layer (medium layer) 22 containing liquid crystal molecules, which are substances having optical characteristics that change in accordance with application of an electrical field, is interposed between the pair of substrates 20 and 21. A sealing portion 23 that seals the liquid crystal layer 22 is provided to be interposed between outer peripheral ends of the pair of substrates 20 and 21. The sealing portion 23 is formed in a rectangular frame shape (endless ring shape) to surround the liquid crystal layer 22. Polarizers 16 are bonded to the outer face sides of both the substrates 20 and 21, respectively.

As shown in FIG. 1 and FIG. 2, the counter substrate 20 has a short side dimension shorter than a short side dimension of the array substrate 21. The counter substrate 20 is bonded to the array substrate 21 with one end in a short side direction (Y-axis direction) aligned with the array substrate 21. Thus, the other end of the array substrate 21 in the short side direction is an exposed portion 21A that protrudes laterally relative to the counter substrate 20 and is exposed. The exposed portion 21A is entirely a non-display region NAA, and is equipped with a driver (mounted component, signal supply unit) 12 and a flexible substrate 13 for supplying various signals related to a display function and a touch panel function to be described below.

The driver 12 shown in FIGS. 1 and 2 is constituted of an LSI chip having an internal drive circuit. The driver 12 is mounted on the exposed portion 21A of the array substrate 21 in a chip-on-glass (COG) manner. The driver 12 processes various signals transmitted by the flexible substrate 13. The driver 12 supplies various signals (for example, image signals, touch signals, and the like) to wiring lines in the display region AA (specifically, source wiring lines 27 and touch wiring lines 30, which will be described later). The flexible substrate 13 has a configuration in which a large number of wiring line patterns are formed on a base material made of a synthetic resin material (for example, a polyimide resin or the like) having insulating properties and flexibility. As shown in FIG. 1 and FIG. 2, one end side of the flexible substrate 13 is connected to the exposed portion 21A of the array substrate 21, and the other end side thereof is connected to an external circuit substrate (control substrate, or the like). The flexible substrate 13 is connected to an end of the exposed portion 21A on a side opposite to the display region AA side in the Y-axis direction with respect to the driver 12.

The liquid crystal panel 11 according to this embodiment has both a display function of displaying an image and a touch panel function of detecting a position (input position) input by a user based on the displayed image. In the liquid crystal panel 11, a touch panel pattern for exhibiting the touch panel function is integrated (in an in-cell form). The touch panel pattern is a so-called projected capacitive type, and the detection type thereof is a self-capacitance type. As shown in FIG. 1, the touch panel pattern is constituted of a plurality of touch electrodes (position detection electrodes) 29 disposed lined up in a matrix on a plate surface of the liquid crystal panel 11. A touch electrode 29 is disposed in the display region AA of the liquid crystal panel 11. Thus, the display region AA of the liquid crystal panel 11 substantially matches a touch region (position input region) in which an input position can be detected, and the non-display region NAA substantially matches a non-touch region (non-position input region) in which an input position cannot be detected. When a user brings his or her finger (position input object), which is a conductor, close to the surface (display surface) of the liquid crystal panel 11 to input a position based on the image of the display region AA of the liquid crystal panel 11 that is visually recognized, capacitance is formed between the finger and the touch electrode 29. Thereby, the capacitance detected by the touch electrode 29 near the finger changes as the finger approaches, and is different from that of the touch electrode 29 farther away from the finger, making it possible to detect an input position based on this. A specific number of touch electrodes 29 installed can be changed appropriately, in addition to the touch electrodes 29 shown in FIG. 1. The touch electrode 29 has a substantially rectangular shape in a plan view, and the dimension of one side of the touch electrode 29 is approximately several mm. Thus, the size of the touch electrode 29 in a plan view is much larger than a pixel to be described later, and is disposed in a range that spans a plurality of pixels in the X-axis direction and the Y-axis direction.

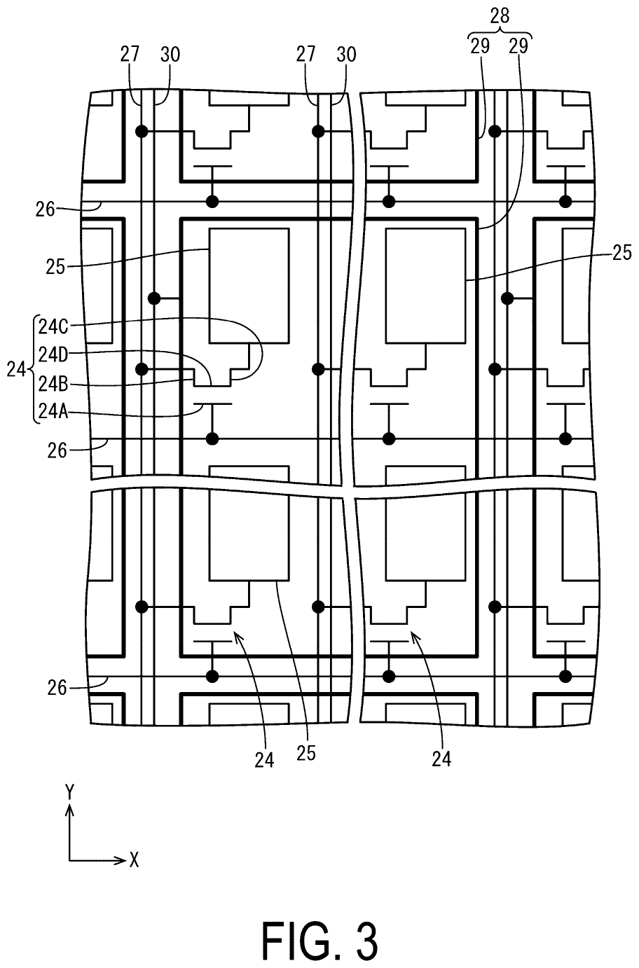

Next, a configuration of the display region AA in the array substrate 21 will be described with reference to FIG. 3. As shown in FIG. 3, at least a second TFT (second transistor) 24 and a pixel electrode 25 are provided on the inner surface of the array substrate 21 in the display region AA. A plurality of the second TFTs 24 and a plurality of the pixel electrodes 25 are provided lined up in a matrix at intervals in the X-axis direction and the Y-axis direction. Gate wiring lines (scanning wiring lines) 26 and source wiring lines (image wiring lines, signal wiring lines) 27 that are orthogonal to (intersecting) each other are disposed around the second TFTs 24 and the pixel electrodes 25. The gate wiring lines 26 extend in the X-axis direction. The source wiring lines 27 extend in the Y-axis direction. The second TFT 24 includes a second gate electrode 24A connected to the gate wiring line 26, a second source electrode 24B connected to the source wiring line 27, a second drain electrode 24C connected to the pixel electrode 25, and a second semiconductor portion 24D connected to the second source electrode 24B and the second drain electrode 24C. The second TFT 24 is driven based on a scanning signal supplied to the second gate electrode 24A by the gate wiring line 26. Then, a potential related to an image signal (data signal) supplied from the driver 12 to the second source electrode 24B through the source wiring line 27 is supplied to the second drain electrode 24C through the second semiconductor portion 24D. As a result, the pixel electrode 25 is charged to the potential related to the image signal. The pixel electrode 25 is disposed in a region surrounded by the gate wiring line 26 and the source wiring line 27, and has a planar shape of, for example, a substantially rectangular shape.

As shown in FIG. 3, a common electrode 28 is formed on the inner surface side of the array substrate 21 in the display region AA so as to overlap all of the pixel electrodes 25. The common electrode 28 extends over substantially the entire display region AA. The common electrode 28 constitutes the touch electrode 29 that has already been described. The common electrode 28 has partition slits that separate adjacent touch electrodes 29. The common electrode 28 is divided into a grid pattern by the partition slits, and is constituted of the plurality of touch electrodes 29 which are electrically independent of each other.

As shown in FIG. 3, a plurality of touch wiring lines (wiring lines, position detection wiring lines) 30 connected to the plurality of touch electrodes 29 are provided on the inner surface side of the array substrate 21 in the display region AA. The touch wiring lines 30 extend in the Y-axis direction and are parallel to the source wiring lines 27. The plurality of touch wiring lines 30 are individually connected to the plurality of touch electrodes 29. A common signal (reference potential signal) related to the display function and a touch signal (position detection signal) related to the touch function are supplied to the touch wiring lines 30 from the driver 12 at different timings (on a time-division basis). The timing when the common signal is supplied from the driver 12 to the touch wiring lines 30 is a display period, and the timing when the touch signal is supplied from the driver 12 to the touch wiring lines 30 is a sensing period (position detection period). During the display period, the common signal is supplied to all of the touch wiring lines 30, and thus all of the touch electrodes 29 are set to a reference potential and function as the common electrodes 28.

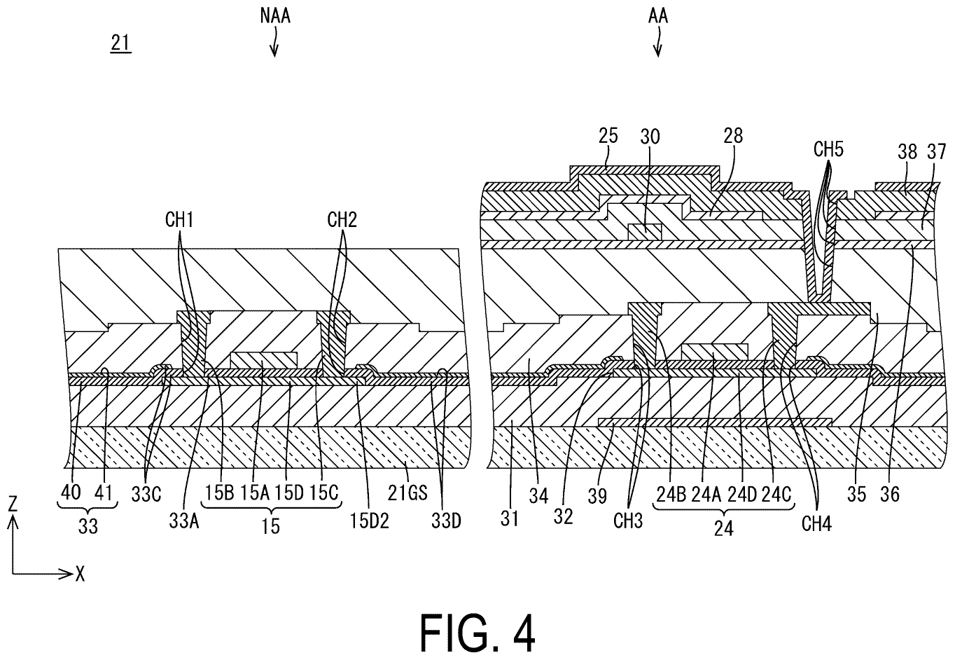

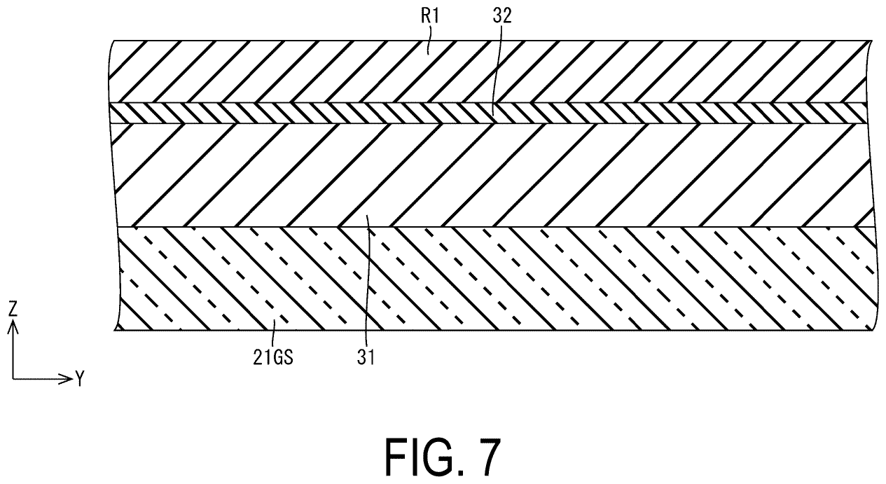

Next, various films layered on the glass substrate (substrate) 21GS of the array substrate 21 will be described in detail with reference to FIG. 4. FIG. 4 shows a cross-sectional configuration of the circuit portion 14 (first TFT 15) in the non-display region NAA and a cross-sectional configuration in the display region AA (second TFT 24). As shown in FIG. 4, at least a first metal film (light shielding film), a base coat film 31, a semiconductor film 32 (see FIG. 7), a gate insulating film (first insulating film) 33, a second metal film (first conductive film), a first interlayer insulating film (second insulating film) 34, a third metal film (second conductive film), a flattening film 35, a second interlayer insulating film 36, a fourth metal film (third conductive film), a third interlayer insulating film 37, a first transparent electrode film, a fourth interlayer insulating film 38, a second transparent electrode film, and an alignment film are formed to be layered on the glass substrate 21GS of the array substrate 21 in this order from the lower layer side (glass substrate 21GS side).

The first metal film, the second metal film, the third metal film and the fourth metal film are each configured as a single layer film made of one type of metal material or configured as a layered film or an alloy made of different types of metal materials, and thus have conductivity and light shielding properties. Specifically, the first metal film is a single layer film made of, for example, Mo (molybdenum) and has a film thickness of, for example, approximately 50 nm. The second metal film is a single layer film made of, for example, Mo (molybdenum) and has a film thickness of, for example, approximately 300 nm. The second metal film is a layered film including, for example, Ti (titanium)/Al (aluminum)/Ti in this order from the upper layer side, and has a film thickness of, for example, approximately 50 nm/approximately 350 nm/approximately 100 nm. The third metal film is a layered film including, for example, Mo/Al/Mo in this order from the upper layer side, and has a film thickness of, for example, approximately 100 nm/approximately 300 nm/approximately 30 nm. The semiconductor film 32 is made of a polysilicon semiconductor material (semiconductor material) having a crystalline substance created by a known method such as laser crystallization, and the polysilicon semiconductor material of the semiconductor film 32, which has a film thickness of, for example, approximately 50 nm, has a higher electron mobility than that of an amorphous silicon semiconductor material or an oxide semiconductor material. The first transparent electrode film and the second transparent electrode film are made of a transparent electrode material such as ITO (indium tin oxide), and each has a film thickness of, for example, approximately 60 nm.

The base coat film 31, the gate insulating film 33, the first interlayer insulating film 34, the second interlayer insulating film 36, the third interlayer insulating film 37 and the fourth interlayer insulating film 38 are all made of SiO₂ (silicon oxide) or SiNₓ (silicon nitride) which is a type of an inorganic material (inorganic resin material). Specifically, the base coat film 31 is a layered film made of SiO₂/SiNₓ in this order from the upper layer side and has a film thickness of, for example, approximately 200 nm/approximately 100 nm. The gate insulating film 33 is a layered film made of SiN/SiO₂ in this order from the upper layer side and has a film thickness of, for example, approximately 50 nm/approximately 100 nm. The first interlayer insulating film 34 is a layered film made of SiNₓ/SiO₂ in this order from the upper layer side and has a film thickness of, for example, approximately 300 nm/approximately 300 nm. The second interlayer insulating film 36 is a single layer film of SiNₓ and has a film thickness of, for example, approximately 100 nm. The third interlayer insulating film 37 is a single layer film of SiNₓ and has a film thickness of, for example, approximately 100 nm. The fourth interlayer insulating film 38 is a single layer film of SiNₓ and has a film thickness of, for example, approximately 200 nm. The flattening film 35 is made of PMMA (acrylic resin), which is a type of organic material (organic resin material), and has a film thickness in the range of, for example, approximately 1 μm to 3 μm. In other words, the flattening film 35 has a film thickness greater than those of the other insulating films 31, 33, 34, 36, 37, and 38 that are made of inorganic materials.

Next, a cross-sectional configuration of the circuit portion 14 will be described in detail. As shown in FIG. 4, the circuit portion 14 includes the first TFT 15. The first TFT 15 includes a first gate electrode (first electrode) 15A, a first source electrode (second electrode) 15B, a first drain electrode (third electrode) 15C, and a first semiconductor portion (semiconductor portion) 15D. Among these, the first semiconductor portion 15D is located on the lowermost layer side with respect to the electrodes 15A to 15C, and is constituted of the semiconductor film 32. Thus, the first TFT 15 can be said to be a so-called top-gate type transistor.

As shown in FIG. 4, the first gate electrode 15A is constituted of a second metal film. The first gate electrode 15A is disposed to overlap the upper layer side of the first semiconductor portion 15D via the gate insulating film 33. The first gate electrode 15A is disposed to overlap the center-side portion of the first semiconductor portion 15D in the X-axis direction (first direction).

As shown in FIG. 4, the first source electrode 15B and the first drain electrode 15C are both constituted of a third metal film. The first source electrode 15B and the first drain electrode 15C are disposed to overlap a portion of the first semiconductor portion 15D on the upper layer side via the gate insulating film 33 and the first interlayer insulating film 34. The first source electrode 15B is disposed to overlap one end-side portion (the left side in FIG. 4) of the first semiconductor portion 15D in the X-axis direction. The first source electrode 15B and the first semiconductor portion 15D are connected to each other through a first contact hole CH1 that is opened to communicate with the gate insulating film 33 and the first interlayer insulating film 34 interposed therebetween. In other words, the first contact hole CH1 is at a connection position between the first source electrode 15B and the first semiconductor portion 15D. The first drain electrode 15C is disposed to overlap the other end-side portion (the right side in FIG. 4) of the first semiconductor portion 15D in the X-axis direction. The first drain electrode 15C and the first semiconductor portion 15D are connected to each other through a second contact hole CH2 that is opened to communicate with the gate insulating film 33 and the first interlayer insulating film 34 interposed therebetween. In other words, the second contact hole CH2 is at a connection position between the first drain electrode 15C and the first semiconductor portion 15D. The first source electrode 15B and the first drain electrode 15C are disposed at positions spaced apart from each other in the X-axis direction with the first gate electrode 15A interposed therebetween. The first contact hole CHI and the second contact hole CH2 are disposed at positions spaced apart from each other in the X-axis direction with the first gate electrode 15A interposed therebetween.

Next, a cross-sectional configuration of the display region AA will be described in detail. As shown in FIG. 4, the second TFT 24 is disposed in the display region AA. The second TFT 24 includes a second gate electrode 24A, a second source electrode 24B, a second drain electrode 24C, and a second semiconductor portion 24D. Among these, the second semiconductor portion 24D is located on the lowermost layer side with respect to the electrodes 24A to 24C, and is constituted of the semiconductor film 32. Thus, the second TFT 24 can be said to be a top-gate type transistor, similar to the first TFT 15.

As shown in FIG. 4, the second gate electrode 24A is constituted of a portion of the second metal film different from the first gate electrode 15A. The second gate electrode 24A is disposed to overlap the upper layer side of the second semiconductor portion 24D via the gate insulating film 33. The second gate electrode 24A is disposed to overlap the center-side portion of the second semiconductor portion 24D in the X-axis direction.

As shown in FIG. 4, the second source electrode 24B is constituted of a portion of the third metal film different from the first source electrode 15B and the first drain electrode 15C. The second drain electrode 24C is constituted of a portion of the third metal film different from the first source electrode 15B, the first drain electrode 15C and the second source electrode 24B. The second source electrode 24B and the second drain electrode 24C are disposed to overlap a portion of the first semiconductor portion 15D on the upper layer side via the gate insulating film 33 and the first interlayer insulating film 34. The second source electrode 24B is disposed to overlap one end-side portion (the left side in FIG. 4) of the second semiconductor portion 24D in the X-axis direction. The second source electrode 24B and the second semiconductor portion 24D are connected to each other through a third contact hole CH3 that is opened to communicate with the gate insulating film 33 and the first interlayer insulating film 34 interposed therebetween. The second drain electrode 24C is disposed to overlap the other end-side portion (the right side in FIG. 4) of the second semiconductor portion 24D in the X-axis direction. The second drain electrode 24C and the second semiconductor portion 24D are connected to each other through a fourth contact hole CH4 that is opened to communicate with the gate insulating film 33 and first interlayer insulating film 34 interposed therebetween. The second source electrode 24B and the second drain electrode 24C are disposed at positions spaced apart from each other in the X-axis direction with the second gate electrode 24A interposed therebetween.

As shown in FIG. 4, the pixel electrode 25 and the common electrode 28 (touch electrode 29) are disposed in the display region AA. The pixel electrode 25 is constituted of a second transparent electrode film. A portion of the pixel electrode 25 is disposed to overlap the second drain electrode 24C. The pixel electrode 25 and the second drain electrode 24C are connected to each other through a fifth contact hole CH5 that is opened to communicate with the flattening film 35, the second interlayer insulating film 36, the third interlayer insulating film 37, and the fourth interlayer insulating film 38 that are interposed therebetween. In addition, slits are opened in the plurality of pixel electrodes 25. The slits are not shown in FIG. 3.

The common electrode 28 is constituted of a first transparent electrode film. As shown in FIG. 4, the common electrode 28 is disposed to overlap all of the pixel electrodes 25 disposed in the display region AA on the lower layer side via the fourth interlayer insulating film 38. A common potential signal set to be at a common potential (reference potential) is supplied to the common electrode 28. When the pixel electrode 25 is charged to a potential based on an image signal transmitted to the source wiring line 26 in association with the driving of the second TFT 24, a potential difference is generated between the pixel electrode 25 and the common electrode 28. Then, a fringe electric field (oblique electric field) is generated between an opening edge of the slit in the pixel electrode 25 and the common electrode 28, the fringe electric field including a component in a normal direction with respect to the plate surface of the array substrate 21 in addition to a component along the plate surface of the array substrate 21. Thus, it is possible to control the alignment state of the liquid crystal molecules included in the liquid crystal layer 22 by using this fringe electrical field, and a predetermined display is performed based on the alignment state of the liquid crystal molecules. That is, an operation mode of the liquid crystal panel 11 according to this embodiment is a fringe field switching (FFS) mode. An opening for preventing a short circuit with the pixel electrode 25 is provided in the common electrode 28 at a position overlapping the fifth contact hole CH5.

Further, as shown in FIG. 4, the touch wiring line 30 is disposed in the display region AA. The touch wiring line 30 is constituted of a fourth metal film. The touch wiring line 30 is disposed at a position overlapping the source wiring line 27 in a plan view. The flattening film 35 and the second interlayer insulating film 36 are interposed between the touch wiring line 30 and the source wiring line 27 that overlap each other, thereby maintaining a state where they are insulated from each other. The third interlayer insulating film 37 is interposed between the touch wiring line 30 and the common electrode 28. The touch wiring line 30 and the touch electrode 29 to be connected thereto are connected to each other through a sixth contact hole opened in the third interlayer insulating film 37 interposed therebetween. The sixth contact hole is not shown in the drawing.

Furthermore, in the display region AA, a light shielding portion 39 is provided at a position overlapping at least the entire region of the second semiconductor portion 24D. The light shielding portion 39 is constituted of a first metal film. The light shielding portion 39 is disposed to overlap the second semiconductor portion 24D on the lower layer side via the base coat film 31. Thus, the light shielding portion 39 can shield light that is emitted from the lower layer side from a backlight device to a channel region of the second semiconductor portion 24D. Thereby, it is possible to suppress fluctuations in the characteristics of the second TFT 24 which may occur when light is emitted to the channel region of the second semiconductor portion 24D.

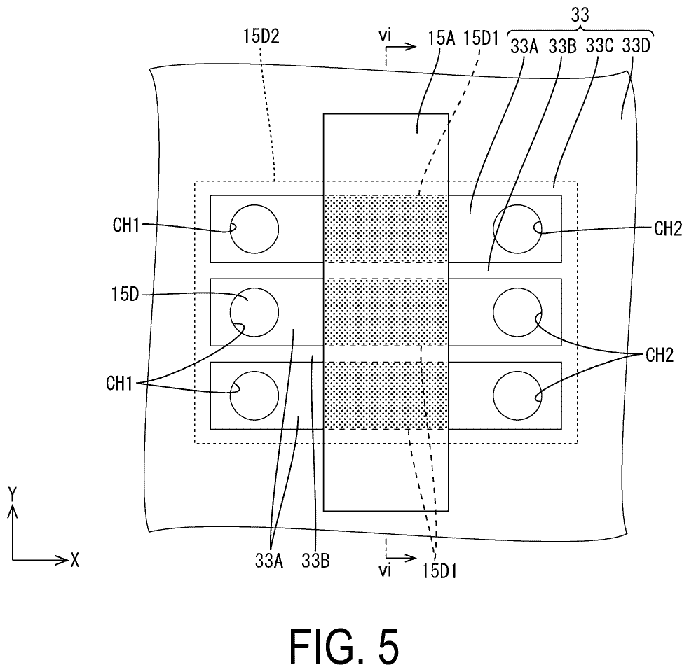

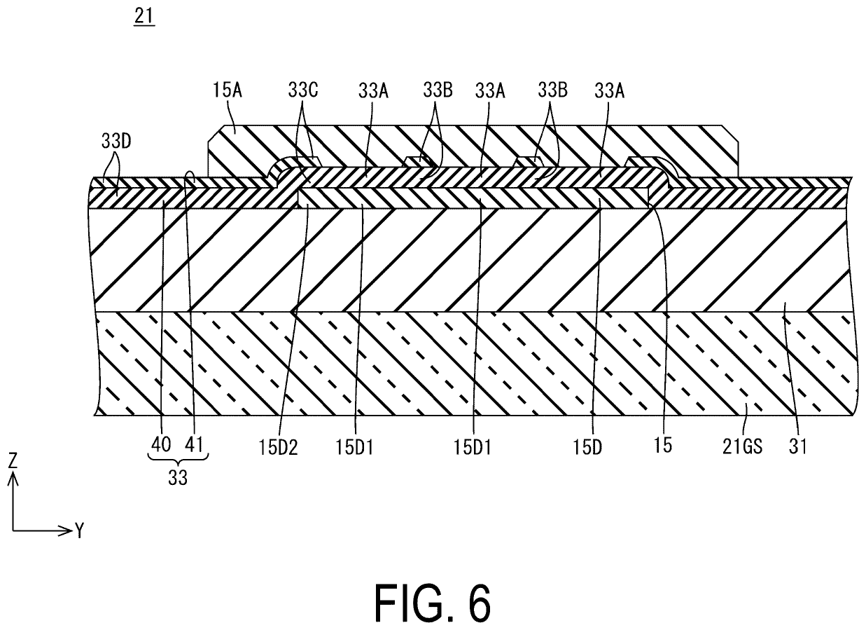

A detailed configuration of the first TFT 15 included in the circuit portion 14 will be described with reference to FIGS. 5 and 6. FIGS. 5 and 6 show only a configuration (first semiconductor portion 15D and gate insulating film 33) of the first TFT 15 on a lower layer side below the first gate electrode 15A. As shown in FIG. 5, the first semiconductor portion 15D included in the first TFT 15 extends in the X-axis direction (first direction). The first semiconductor portion 15D has a substantially rectangular shape that is horizontally elongated in a plan view. The first semiconductor portion 15D has a width dimension (dimension in the Y-axis direction) according to the amount of current flowing through a circuit to which the first TFT 15 belongs in the circuit portion 14. In particular, the first TFT 15 belonging to a buffer circuit included in the circuit portion 14 handles a large amount of current, and thus, the first semiconductor portion 15D constituting the first TFT 15 has a width dimension larger than those of the first TFT 15 and second TFT 24 belonging to other circuits.

As shown in FIG. 5, the first gate electrode 15A extends in the Y-axis direction (second direction) so as to intersect the extension direction of the first semiconductor portion 15D. The first gate electrode 15A has a substantially rectangular shape that is vertically elongated in a plan view. The first gate electrode 15A has a length dimension (dimension in the Y-axis direction) larger than the width dimension of the first semiconductor portion 15D, and has a width dimension (dimension in the X-axis direction) smaller than the length dimension (dimension in the X-axis direction) of the first semiconductor portion 15D. The first gate electrode 15A is disposed across the first semiconductor portion 15D so as to overlap the entire width of the first semiconductor portion 15D. Both ends of the first gate electrode 15A in the length direction (Y-axis direction) are disposed not to overlap the first semiconductor portion 15D. The first gate electrode 15A is disposed to overlap the center-side portion of the first semiconductor portion 15D in the length direction (X-axis direction). Both end-side portions of the first semiconductor portion 15D in the longitudinal direction are disposed not to overlap the first gate electrode 15A. The first contact hole CH1 and the second contact hole CH2 are disposed to overlap the both end-side portions of the first semiconductor portion 15D in the longitudinal direction.

As described above, when the first semiconductor portion 15D constituting the first TFT 15 is formed wide and the amount of current handled is increased, there is a concern that the transistor characteristics may deteriorate due to self-heating. In the related art, a first semiconductor portion is divided into a plurality of small island regions, and thus the sum of the lengths of outer peripheral ends of the plurality of small island regions became larger, thereby increasing the possibility of defects occurring near the outer peripheral ends (deterioration of voltage resistance and the occurrence of leakage due to minute protrusions).

In this regard, in this embodiment, the gate insulating film 33 interposed between the first gate electrode 15A and the first semiconductor portion 15D is configured to include a first thick portion 33A and a second thick portion 33B having a film thickness greater than that of the first thick portion 33A, as shown in FIG. 6. The first thick portion 33A and the second thick portion 33B are both disposed at positions overlapping both the first gate electrode 15A and the first semiconductor portion 15D. In this embodiment, three (at least two) first thick portions 33A are disposed at positions spaced apart from each other in the Y-axis direction. The second thick portion 33B is disposed to be interposed between two first thick portions 33A in the Y-axis direction. In this embodiment, two second thick portions 33B are disposed spaced apart from each other in the Y-axis direction. The film thickness of the first thick portion 33A is set to such a size that a channel region 15D1 is generated in a portion of the first semiconductor portion 15D which overlaps the first thick portion 33A when a predetermined voltage (a voltage equal to or greater than a threshold voltage) is applied to the first gate electrode 15A. In FIG. 5, a range in which the channel region 15D1 is generated in the first semiconductor portion 15D is shown in a shaded shape. On the other hand, the film thickness of the second thick portion 33B is set to such a size that the channel region 15D1 is not generated in a portion of the first semiconductor portion 15D which overlaps the second thick portion 33B even when a predetermined voltage is applied to the first gate electrode 15A. That is, a voltage applied to the first gate electrode 15A is set to a value so that the channel region 15D1 is generated in the portion of the first semiconductor portion 15D which overlaps the first thick portion 33A, but the channel region 15D1 is not generated in the portion of the first semiconductor portion 15D which overlaps the second thick portion 33B.

According to such a configuration, when a predetermined voltage is applied to the first gate electrode 15A, the channel region 15D1 is generated in the first semiconductor portion 15D. The channel region 15D1 is selectively generated in a portion of the first semiconductor portion 15D which overlaps the first thick portion 33A having a smaller film thickness, and is not generated in a portion which overlaps the second thick portion 33B having a larger film thickness. That is, the channel region 15D1 can be generated in each of three locations spaced apart from each other in the Y-axis direction in the first semiconductor portion 15D, and thus it is possible to reduce self-heating while securing a sufficient amount of current. As in the related art, it is not necessary to divide the first semiconductor portion 15D into a plurality of small island regions, and thus the length of an outer peripheral end 15D2 of the first semiconductor portion 15D is smaller than the sum of the lengths of outer peripheral ends of the plurality of small island regions in the related art. Thereby, the possibility of defects occurring near the outer peripheral end 15D2 of the first semiconductor portion 15D is decreased, and consequently, it is possible to improve a yield.

As shown in FIG. 6, the gate insulating film 33 has a layered structure of a lower insulating film 40 and an upper insulating film 41. The lower insulating film 40 is disposed on the upper layer side of the first semiconductor portion 15D. The lower insulating film 40 is made of, for example, SiO₂ and has a film thickness of, for example, approximately 100 nm. The upper insulating film 41 is located on the upper layer side of the lower insulating film 40 and disposed on the lower layer side of the first gate electrode 15A. The upper insulating film 41 is made of a material different from that of the lower insulating film 40. The upper insulating film 41 has a film thickness smaller than that of the lower insulating film 40. The upper insulating film 41 is made of, for example, SiN and has a film thickness of, for example, approximately 50 nm. In this manner, the gate insulating film 33 is formed to have a layered structure of the lower insulating film 40 and the upper insulating film 41, which are made of different materials, and thus the first thick portion 33A and the second thick portion 33B, which have different film thicknesses, can be easily provided.

In this embodiment, as shown in FIG. 6, the first thick portion 33A is constituted of the lower insulating film 40, while the second thick portion 33B is constituted of the upper insulating film 41 and the lower insulating film 40. According to such a configuration, during manufacturing, the lower insulating film 40 and the upper insulating film 41 are sequentially formed, and then the upper insulating film 41 is selectively removed, and thus the first thick portion 33A constituted of the lower insulating film 40 and the second thick portion 33B constituted of the lower insulating film 40 and the upper insulating film 41 can be easily provided.

In addition, as shown in FIG. 5, the first thick portion 33A is provided to extend not only to an area overlapping the first gate electrode 15A in the X-axis direction, but also to an area not overlapping the first gate electrode 15A. Specifically, the first thick portion 33A is provided in the gate insulating film 33 over a range from the first contact hole CH1 to the second contact hole CH2 in the X-axis direction. The first thick portion 33A has a rectangular shape that is horizontally elongated in a plan view, and is configured such that the length thereof is substantially the same as or slightly smaller than the length of the first semiconductor portion 15D, and the width dimension thereof is approximately ⅓ of the width dimension of the first semiconductor portion 15D. In this manner, the first thick portion 33A is extended to a range not overlapping the first gate electrode 15A in the X-axis direction. Thus, as compared to a case where the first thick portion is provided only in an area overlapping the first gate electrode 15A in the X-axis direction, even when the first thick portion 33A and the first gate electrode 15A are misaligned relative to each other in the X-axis direction due to manufacturing reasons, a channel region 15D1 can be generated in the first semiconductor portion 15D. In this embodiment, the width dimensions of the three first thick portions 33A are substantially equal to each other.

As shown in FIG. 6, the gate insulating film 33 includes a third thick portion 33C having a film thickness greater than that of the first thick portion 33A. The third thick portion 33C is disposed to overlap the outer peripheral end 15D2 of the first semiconductor portion 15D. The third thick portion 33C has the same film thickness as that of the second thick portion 33B. That is, the third thick portion 33C is constituted of the upper insulating film 41 and the lower insulating film 40 in the same manner as the second thick portion 33B. In this manner, the outer peripheral end 15D2 of the first semiconductor portion 15D is covered by the third thick portion 33C having a film thickness greater than that of the first thick portion 33A from the upper layer side, further reducing the possibility of defects occurring near the outer peripheral end 15D2 of the first semiconductor portion 15D. Thereby, it is possible to further improve a yield. Furthermore, the third thick portion 33C has the same film thickness as that of the second thick portion 33B, which makes it easier to perform manufacturing than when all of the first thick portion 33A, the second thick portion 33B, and the third thick portion 33C have different film thicknesses.

As shown in FIG. 6, the gate insulating film 33 includes a fourth thick portion 33D having a film thickness greater than that of the first thick portion 33A. The fourth thick portion 33D constitutes a portion of the gate insulating film 33 which does not overlap the first semiconductor portion 15D in a plan view. The fourth thick portion 33D has the same film thickness as that of the second thick portion 33B. That is, the fourth thick portion 33D is constituted of the upper insulating film 41 and the lower insulating film 40 in the same manner as the second thick portion 33B and the third thick portion 33C.

This embodiment has the above-described structure, and a manufacturing method for the liquid crystal panel 11 will be subsequently described. The manufacturing method for the liquid crystal panel 11 includes a counter substrate manufacturing step (CF substrate manufacturing step) of manufacturing the counter substrate 20, an array substrate manufacturing step of manufacturing the array substrate 21, and a bonding step of bonding the manufactured counter substrate 20 and array substrate 21 together. Hereinafter, among the above steps, the array substrate manufacturing step will be described.

The array substrate manufacturing step includes at least a first step of forming and patterning the first metal film, a second step of forming the base coat film 31, a third step of forming the semiconductor film 32, performing a laser crystallization process, and then patterning the semiconductor film 32, a fourth step of forming and patterning the gate insulating film 33, a fifth step of forming and patterning the second metal film, a sixth step of forming and patterning the first interlayer insulating film 34, a seventh step of forming and patterning the third metal film, an eighth step of forming the flattening film 35, a ninth step of forming the second interlayer insulating film 36, a tenth step of forming and patterning the fourth metal film, an eleventh step of forming the third interlayer insulating film 37, a twelfth step of forming and patterning the first transparent electrode film, a thirteenth step of forming and patterning the fourth interlayer insulating film 38, a fourteenth step of forming and patterning the second transparent electrode film, and a fifteenth step of forming the alignment film and performing an alignment process. Among these, the third and fourth steps will be described in detail below with reference to FIGS. 7 to 15. FIGS. 7 to 15 show the same cross-sectional configuration as that in FIG. 6.

The term “patterning” described above means a process of a film based on a general photolithography method. Specifically, the process, that is, the patterning of a film to be processed is performed by forming a photoresist film on the film to be processed, exposing the photoresist film with an exposure device through a photomask having a predetermined pattern, developing the photoresist film, and performing etching through the developed photoresist film.

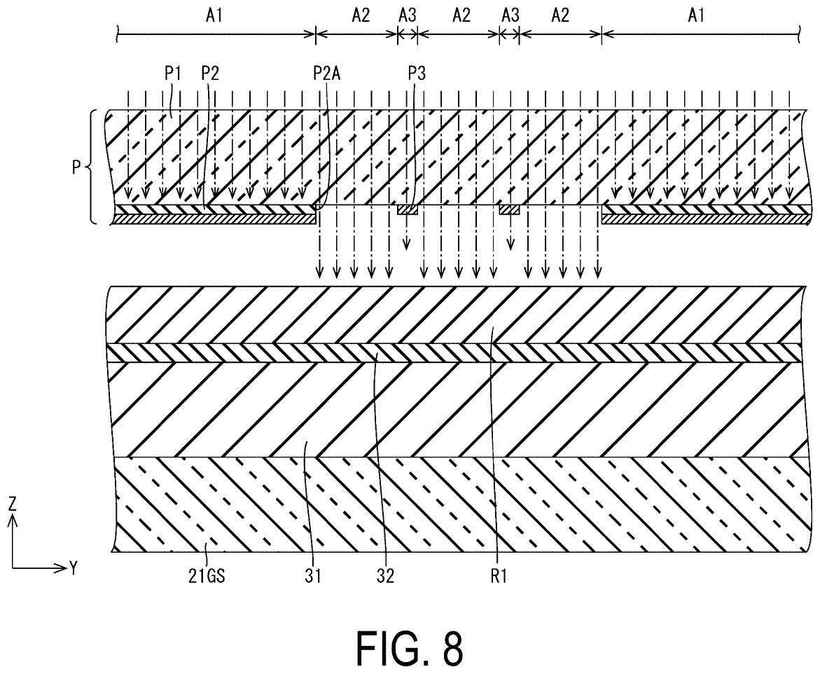

In the third step, the semiconductor film 32 is formed, and then a laser crystallization process is performed on the semiconductor film 32, thereby making the semiconductor film 32 polycrystalline. Next, as shown in FIG. 7, a first resist film R1 is formed in a solid state on the upper layer side of the semiconductor film 32. Thereafter, the first resist film R1 is exposed using an exposure device and a photomask P shown in FIG. 8 (first exposure step). The first resist film R1 used in the third step is made of a negative photosensitive material. Here, the photomask P will be described. As shown in FIG. 8, the photomask P includes a transparent base material P1 with sufficiently high light transmittance, a light shielding film P2 formed on the main surface of the base material P1, and a semi-transmissive film P3 formed on the main surface of the base material P1 and partially layered on the light shielding film P2. That is, the photomask P is a so-called half-tone mask. The light shielding film P2 blocks exposure light from a light source of the exposure device, and the transmittance of the exposure light is set to approximately 0%. The light shielding film P2 has a partial opening P2A. The opening P2A has a size equal to or larger than the resolution of the exposure device, and can transmit light within its formation range. The semi-transmissive film P3 transmits exposure light from the light source of the exposure device with a predetermined transmittance. The semi-transmissive film P3 has a transmittance of exposure light which is higher than the transmittance of the exposure light of the light shielding film P2, and is, for example, approximately 10% to 70%.

As shown in FIG. 8, the light shielding film P2 is configured such that a plurality of openings P2A are disposed in an island-shaped area that overlaps a formation position for the first semiconductor portions 15D to be formed in the non-display region NAA, and in an island-shaped area that overlaps a formation position for the second semiconductor portions 24D to be formed in the display region AA. The semi-transmissive film P3 is disposed in an area overlapping a part of each opening P2A disposed in the non-display region NAA, in addition to an area overlapping the light shielding film P2. More specifically, the semi-transmissive film P3 is disposed in an area overlapping a formation position for the second thick portion 33B to be formed of the gate insulating film 33 in the non-display region NAA.

As shown in FIG. 8, in the photomask P, an area in which the light shielding film P2 is formed is a light shielding region A1 in which light is blocked. The transmittance of light in the light shielding region A1 is approximately 0%. In the photomask P, a portion of the formation range for the opening P2A which does not overlap the semi-transmissive film P3 is a transmissive region A2 in which light is transmitted. Three transmissive regions A2 are disposed at positions spaced apart from each other in the Y-axis direction (positions that overlap the positions where the first thick portions 33A are to be formed) at formation positions for the first semiconductor portions 15D to be formed. The transmittance of light in the transmissive region A2 is approximately 100%. In the photomask P, a portion of the formation range for the opening P2A which overlaps the semi-transmissive film P3 is a semi-transmissive region A3 where light is half transmitted. Two semi-transmissive regions A3 are disposed at positions spaced apart from each other in the Y-axis direction (positions that overlap the positions where the second thick portions 33B are to be formed) at formation positions for the first semiconductor portions 15D to be formed. In other words, the transmissive regions A2 and the semi-transmissive regions A3 are disposed lined up alternately in the Y-axis direction at the formation positions for the first semiconductor portions 15D to be formed. The transmittance of light in the semi-transmissive region A3 is higher than the transmittance in the light shielding region A1 and lower than the transmittance in the transmissive region A2, and is, for example, approximately 10% to 70%. The light shielding regions A1, the transmissive regions A2 and the semi-transmissive regions A3 constitute an exposure pattern in the photomask P.

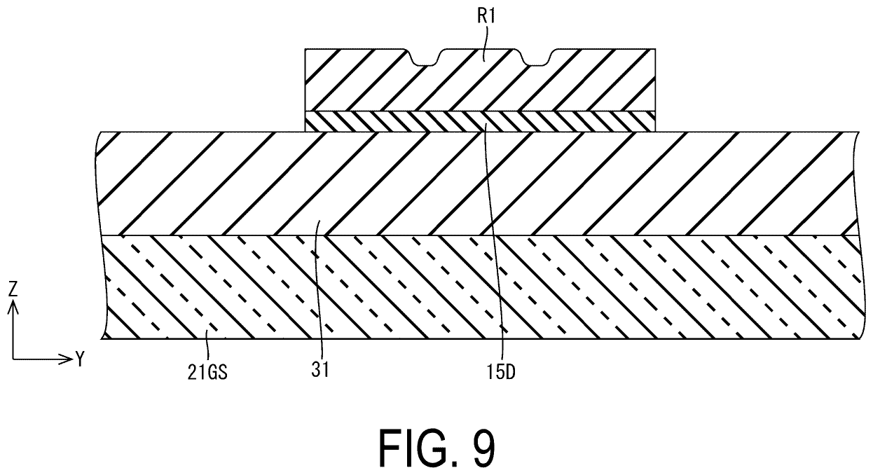

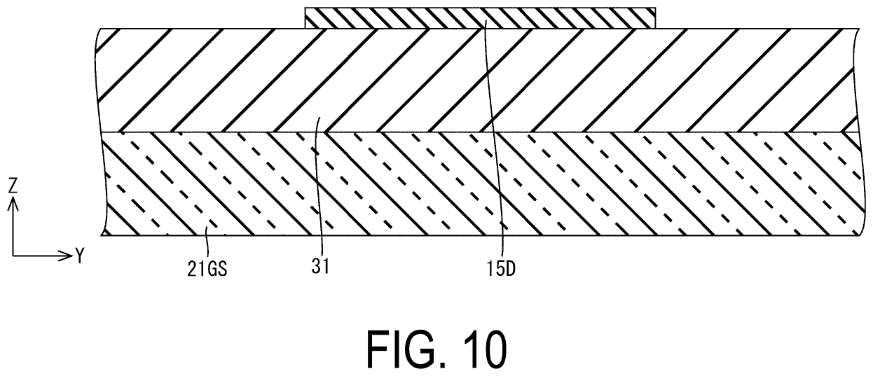

In the third step, the first resist film R1 is irradiated with exposure light emitted from the light source of the exposure device through the photomask P configured as described above. The amount of exposure of the first resist film R1 varies for each portion overlapping each of the regions A1 to A3 of the photomask P, as shown in FIG. 8. That is, in the first resist film R1, the portion overlapping the light shielding region A1 is hardly exposed and is left unexposed, the portion overlapping the transmissive region A2 is sufficiently exposed, and the portion overlapping the semi-transmissive region A3 is exposed with a smaller amount of light than the portion overlapping the light shielding region A1. The first resist film R1 used in the third step is made of a negative photosensitive material. Thus, when the first resist film R1 is developed after the exposure (first development step), as shown in FIG. 9, the unexposed portions of the first resist film R1 (portions overlapping the light shielding regions A1) are removed, the exposed portions (portions overlapping the transmissive regions A2) remain, and the semi-exposed portions (portions overlapping the semi-transmissive regions A3) remain with film thicknesses corresponding to the amount of exposure, that is, film thicknesses smaller than those of the exposed portions. In this manner, in the first resist film R1, portions of the photomask P which overlap the transmissive regions A2 and the semi-transmissive regions A3 selectively remain. When the semiconductor film 32 is etched using the first resist film R1 developed in this manner as a mask (first etching step), the first semiconductor portion 15D located in an area overlapping the transmissive regions A2 and the semi-transmissive regions A3 of the photomask P is provided. When the etching is terminated, the first resist film R1 is removed by ashing (first ashing step), as shown in FIG. 10.

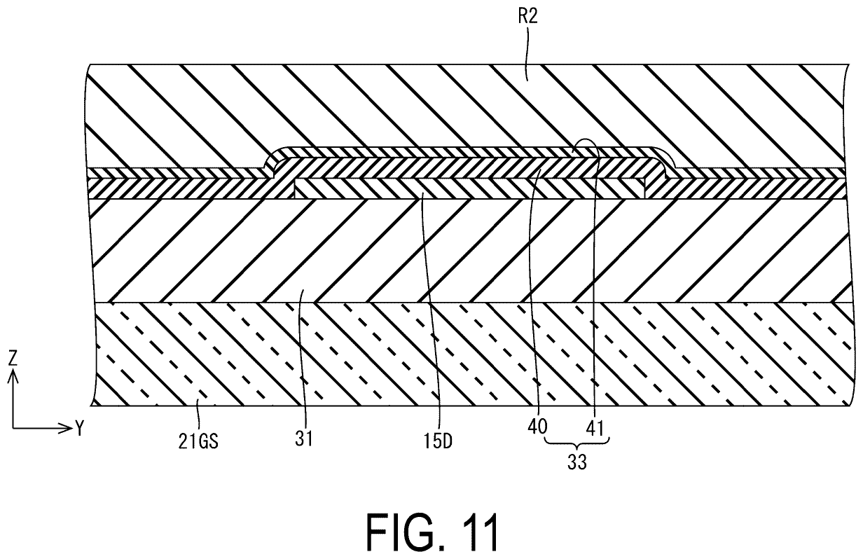

After the third step is performed as described above, the fourth step is performed. In the fourth step, as shown in FIG. 11, the lower insulating film 40 constituting the gate insulating film 33 is first formed in a solid state, the upper insulating film 41 is formed in a solid state on the upper layer side of the lower insulating film 40, and then the second resist film R2 is formed in a solid state on the upper layer side of the upper insulating film 41. The second resist film R2 used in the fourth step is made of a positive photosensitive material. Thereafter, the second resist film R2 is exposed using an exposure device and a photomask P (second exposure step). The photomask P used in the second exposure step of the fourth step has the same exposure pattern (light shielding region A1, transmissive region A2, and semi-transmissive region A3) as the photomask P used in the first exposure step of the third step described above. In this manner, the photomasks P with the same exposure pattern can be used in the first exposure step of exposing the first resist film R1 and the second exposure step of exposing the second resist film R2, which is suitable for reducing costs associated with the equipment required for manufacturing.

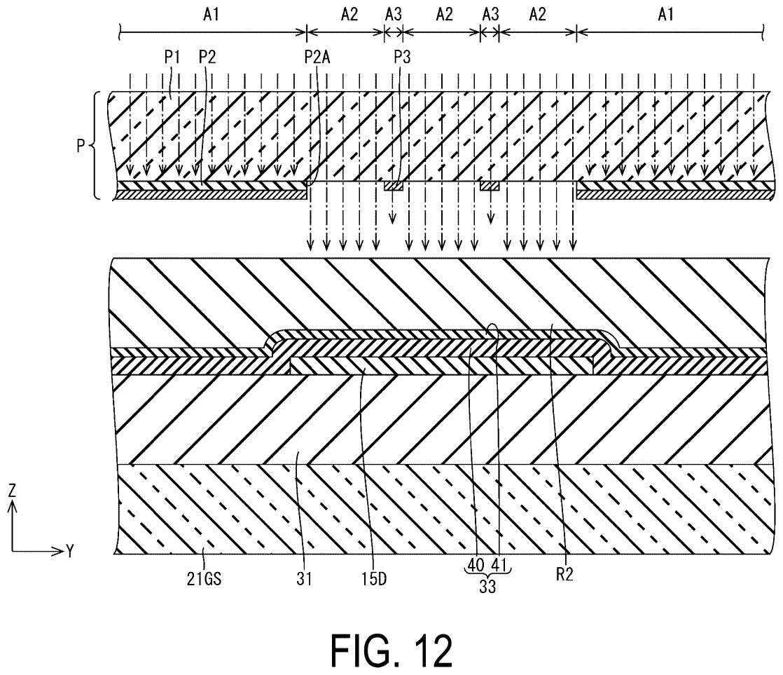

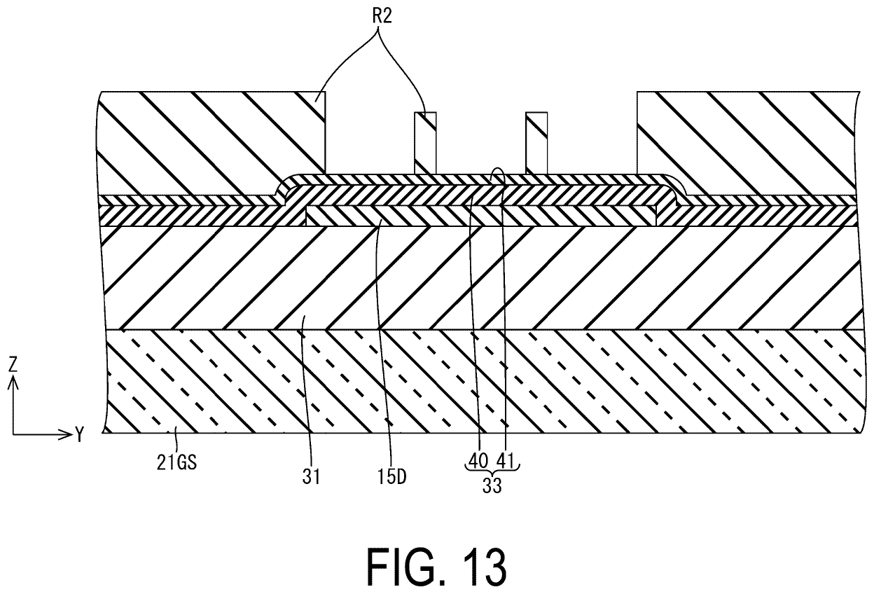

In the fourth step, the second resist film R2 is irradiated with exposure light emitted from the light source of the exposure device through the photomask P having the same exposure pattern as the photomask P used in the first exposure step of the third step. The amount of exposure of the second resist film R2 varies for each portion overlapping each of the regions A1 to A3 of the photomask P, as shown in FIG. 12. That is, in the second resist film R2, the portion of overlapping the light shielding region A1 is hardly exposed, the portion overlapping the transmissive region A2 is sufficiently exposed, and the portion overlapping the semi-transmissive region A3 is exposed with a smaller amount of light than the portion overlapping the transmissive region A2. The second resist film R2 used in the third step is made of a positive photosensitive material. Thus, when the second resist film R2 is developed after the exposure (second development step), as shown in FIG. 13, the exposed portions of the second resist film R2 (portions overlapping the transmissive regions A2) are removed, the unexposed portions (portions overlapping the light shielding regions A1) remain, and the semi-exposed portions (portions overlapping the semi-transmissive regions A3) remain with film thicknesses corresponding to the amount of exposure, that is, film thicknesses smaller than those of the unexposed portions. In this manner, in the second resist film R2, the portions of the photomask P which overlap the light shielding regions A1 and the semi-transmissive regions A3 selectively remain.

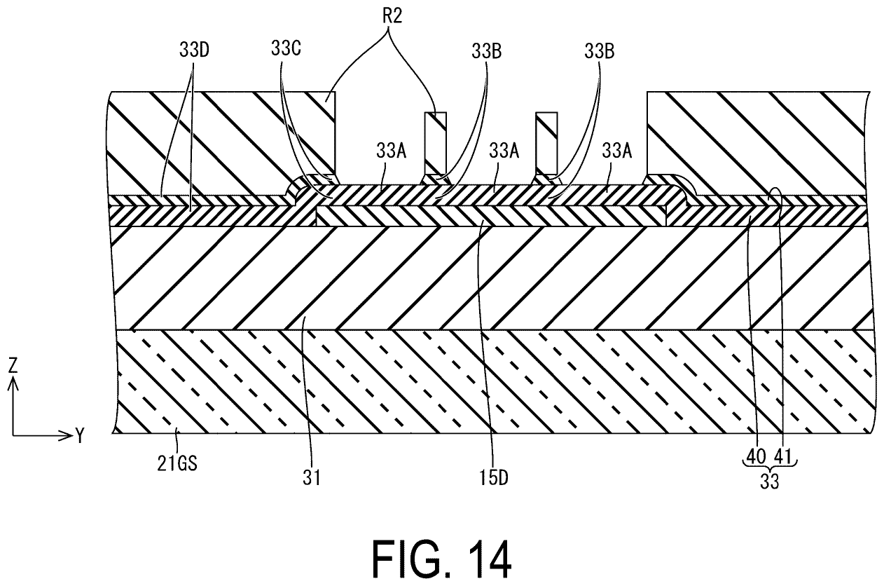

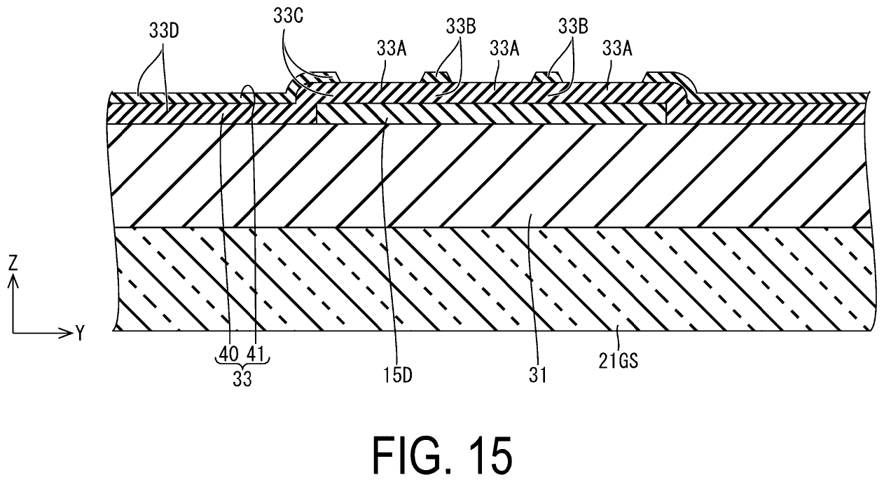

The gate insulating film 33 is etched using the second resist film R2 developed in this manner as a mask (second etching step). In this etching, etching conditions (such as the type of etching gas in the case of dry etching, and such as the type of etching solution in the case of wet etching) are set such that an etching rate for the upper insulating film 41 constituting the gate insulating film 33 is high and an etching rate for the lower insulating film 40 is low. When the second etching step is performed, as shown in FIG. 14, in the upper insulating film 41 constituting the gate insulating film 33, a portion that is exposed without being covered by the second resist film R2 (an area overlapping the transmissive region A2 of the photomask P) is selectively removed, but a portion that is covered by the second resist film R2 (an area overlapping the light shielding region A1 and the semi-transmissive region A3 of the photomask P) remains unremoved. The lower insulating film 40 constituting the gate insulating film 33 is not entirely removed, including an area overlapping the transmissive region A2. Thereby, in the gate insulating film 33, it is possible to easily provide the first thick portion 33A located in an area overlapping the transmissive region A2 of the photomask P and constituted of the lower insulating film 40, the second thick portion 33B located in an area overlapping the semi-transmissive region A3 and constituted of the lower insulating film 40 and the upper insulating film 41, and the third thick portion 33C and the fourth thick portion 33D located in an area overlapping the light shielding region A1 and each constituted of the lower insulating film 40 and the upper insulating film 41. When the etching is terminated, the second resist film R2 is removed by ashing (second ashing step), as shown in FIG. 15. When the fifth step is performed after the fourth step is terminated in this manner, the second metal film is patterned to provide the first gate electrode 15A (see FIG. 6) and the second gate electrode 24A (see FIG. 4).

As described above, the first TFT (transistor) 15 of this embodiment includes the first semiconductor portion (semiconductor portion) 15D extending in a first direction and made of a semiconductor material, the first gate electrode (first electrode) 15A extending in a second direction intersecting the first direction and disposed to overlap a portion of the first semiconductor portion 15D, the gate insulating film (first insulating film) 33 interposed between the first gate electrode 15A and the first semiconductor portion 15D, the first source electrode (second electrode) 15B disposed to overlap a portion of the first semiconductor portion 15D and connected to the first semiconductor portion 15D, and the first drain electrode (third electrode) 15C disposed to overlap a portion of the first semiconductor portion 15D at a position spaced apart from a connection position between the first source electrode 15B and the first semiconductor portion 15D in the first direction and connected to the first semiconductor portion 15D, the gate insulating film 33 includes the first thick portion 33A and the second thick portion 33B having a film thickness greater than that of the first thick portion 33A, at least two first thick portions 33A are disposed at intervals in the second direction at a position overlapping both the first gate electrode 15A and the first semiconductor portion 15D, and the second thick portion 33B is disposed to be interposed between the two first thick portions 33A in the second direction at a position overlapping both the first gate electrode 15A and the first semiconductor portion 15D.

When a voltage equal to or greater than a threshold voltage of the first TFT 15 is applied to the first gate electrode 15A, the channel region 15D1 is generated in the first semiconductor portion 15D. Thus, electrons move between the first source electrode 15B and the first drain electrode 15C via the channel region 15D1. Here, the gate insulating film 33 interposed between the first gate electrode 15A and the first semiconductor portion 15D includes the first thick portion 33A and the second thick portion 33B having a film thickness greater than that of the first thick portion 33A. Thus, the channel region 15D1 is selectively generated in a portion of the first semiconductor portion 15D which overlaps the first thick portion 33A, and is not generated in a portion overlapping the second thick portion 33B. That is, the channel region 15D1 can be generated in each of at least two locations in the first semiconductor portion 15D which are spaced apart from each other in the second direction, and thus it is possible to reduce self-heating while securing a sufficient amount of current. As in the related art, it is not necessary to divide the first semiconductor portion 15D into a plurality of small island regions, and thus the length of an outer peripheral end 15D2 of the first semiconductor portion 15D is smaller than the sum of the lengths of outer peripheral ends of the plurality of small island regions in the related art. Thereby, the possibility of defects occurring near the outer peripheral end 15D2 of the first semiconductor portion 15D is decreased, and consequently, it is possible to improve a yield.

Furthermore, the gate insulating film 33 has a layered structure of the lower insulating film 40 disposed on the upper layer side of the first semiconductor portion 15D, and the upper insulating film 41 disposed on the upper layer side of the lower insulating film 40 and made of a material different from that of the lower insulating film 40. In this manner, the gate insulating film 33 is formed to have a layered structure of the lower insulating film 40 and the upper insulating film 41, which are made of different materials, and thus the first thick portion 33A and the second thick portion 33B, which have different film thicknesses, can be easily provided.

In addition, the first thick portion 33A is made of a lower insulating film 40, and the second thick portion 33B is made of an upper insulating film 41 and a lower insulating film 40. During manufacture, the lower insulating film 40 and the upper insulating film 41 are formed in sequence, and then the upper insulating film 41 is selectively removed, making it possible to easily provide the first thick portion 33A made of the lower insulating film 40 and the second thick portion 33B made of the lower insulating film 40 and the upper insulating film 41.

In addition, the gate insulating film 33 includes the third thick portion 33C having a film thickness greater than that of the first thick portion 33A, and the third thick portion 33C is disposed to overlap the outer peripheral end 15D2 of the first semiconductor portion 15D. The outer peripheral end 15D2 of the first semiconductor portion 15D is covered by the third thick portion 33C having a film thickness greater than that of the first thick portion 33A from the upper layer side, further reducing the possibility of defects occurring near the outer peripheral end 15D2 of the first semiconductor portion 15D. Thereby, it is possible to further improve a yield.

In addition, the third thick portion 33C has the same film thickness as that of the second thick portion 33B. It makes it easier to perform manufacturing than when all of the first thick portion 33A, the second thick portion 33B, and the third thick portion 33C have different film thicknesses.

Further, in the manufacturing method for the first TFT 15 according to this embodiment, the semiconductor film 32 made of a semiconductor material is formed, the first resist film R1 made of a photosensitive material is formed on the upper layer side of the semiconductor film 32, the first resist film R1 is exposed and developed, and the semiconductor film 32 is etched using the first resist film R1 as a mask, thereby providing the first semiconductor portion 15D extending in a first direction. The gate insulating film 33 is formed on the upper layer side of the first semiconductor portion 15D, the second resist film R2 made of a photosensitive material is formed on the upper layer side of the gate insulating film 33, the second resist film R2 is exposed and developed, and the gate insulating film 33 is etched using the second resist film R2 as a mask, thereby forming at least two first thick portions 33A that overlap the first semiconductor portion 15D and are disposed at intervals in a second direction intersecting the first direction, and the second thick portion 33B that is disposed to be interposed between the two first thick portion 33A in the second direction at a position overlapping the first semiconductor portion 15D and has a film thickness greater than that of the first thick portion 33A. The first conductive film is formed on the upper layer side of the gate insulating film 33 and is patterned, thereby providing the first gate electrode 15A disposed to extend in the second direction and overlap a portion of the first semiconductor portion 15D, and disposed to overlap at least the two first thick portions 33A and the second thick portion 33B. The second conductive film is formed on the upper layer side of the first gate electrode 15A and is patterned, thereby providing the first source electrode 15B disposed to overlap a portion of the first semiconductor portion 15D and connected to the first semiconductor portion 15D, and the first drain electrode 15C that is disposed to overlap a portion of the first semiconductor portion 15D at a position spaced apart from a connection position between the first source electrode 15B and the first semiconductor portion 15D in the first direction, and is connected to the first semiconductor portion 15D.

After the semiconductor film 32 and the first resist film R1 are sequentially formed, the first resist film R1 is exposed and developed. When the semiconductor film 32 is etched through the patterned first resist film R1, the first semiconductor portion 15D is provided. When the gate insulating film 33 and the second resist film R2 are sequentially formed on the upper layer side of the first semiconductor portion 15D, the second resist film R2 is exposed and developed. When the gate insulating film 33 is etched through the patterned second resist film R2, the first thick portion 33A and the second thick portion 33B are provided. The first conductive film is formed on the upper layer side of the gate insulating film 33 and is patterned, thereby providing the first gate electrode 15A. The second conductive film is formed on the upper layer side of the first gate electrode 15A and is patterned, thereby providing the first source electrode 15B and the first drain electrode 15C.

When a voltage equal to or greater than a threshold voltage of the first TFT 15 manufactured in this manner is applied to the first gate electrode 15A, the channel region 15D1 is generated in the first semiconductor portion 15D. Thus, electrons move between the first source electrode 15B and the first drain electrode 15C via the channel region 15D1. Here, the gate insulating film 33 interposed between the first gate electrode 15A and the first semiconductor portion 15D includes the first thick portion 33A and the second thick portion 33B having a film thickness greater than that of the first thick portion 33A. Thus, the channel region 15D1 is selectively generated in a portion of the first semiconductor portion 15D which overlaps the first thick portion 33A, and is not generated in a portion overlapping the second thick portion 33B. That is, the channel region 15D1 can be generated in each of at least two locations in the first semiconductor portion 15D which are spaced apart from each other in the second direction, and thus it is possible to reduce self-heating while securing a sufficient amount of current. As in the related art, it is not necessary to divide the first semiconductor portion 15D into a plurality of small island regions, and thus the length of an outer peripheral end 15D2 of the first semiconductor portion 15D is smaller than the sum of the lengths of outer peripheral ends of the plurality of small island regions in the related art. Thereby, the possibility of defects occurring near the outer peripheral end 15D2 of the first semiconductor portion 15D is decreased, and consequently, it is possible to improve a yield.

In addition, the first resist film R1 made of a negative photosensitive material is formed on the upper layer side of the semiconductor film 32, the first resist film R1 is exposed to light through the photomask P having the light shielding region A1 that is disposed not to overlap a formation area for the first semiconductor portion 15D to be formed and blocks light, at least two transmissive regions A2 that overlap the formation area for the first semiconductor portion 15D to be formed, are disposed at intervals in the second direction, and transmit light, and the semi-transmissive region A3 that overlaps the formation area for the first semiconductor portion 15D to be formed, are disposed to be interposed between the two transmissive regions A2 in the second direction, and has a light transmittance higher than a light transmittance of the light shielding region A1 and lower than that of the transmissive region A2, the first resist film R1 is then developed, the second resist film R2 made of a positive photosensitive material is formed on the upper layer side of the gate insulating film 33, and the second resist film R2 is exposed to light through the photomask P and then developed.

The first resist film R1 formed on the upper layer side of the semiconductor film 32 is exposed through the photomask P. The amount of exposure of the first resist film R1 varies for each portion overlapping each region of the photomask P. That is, in the first resist film R1, the portion overlapping the light shielding region A1 is hardly exposed, the portion overlapping the transmissive region A2 is sufficiently exposed, and the portion overlapping the semi-transmissive region A3 is exposed with a smaller amount of light than the portion overlapping the transmissive region A2. The first resist film R1 is made of a negative photosensitive material, and thus, when the first resist film R1 is developed, the unexposed portion (the portion overlapping the light shielding region A1) is removed, the exposed portion (the portion overlapping the transmissive region A2) remains, and the semi-exposed portion (the portion overlapping the semi-transmissive region A3) remains with a film thickness corresponding to the amount of exposure. The semiconductor film 32 is etched using the developed first resist film R1 as a mask, thereby providing the first semiconductor portion 15D located in an area overlapping the transmissive region A2 and the semi-transmissive region A3 of the photomask P.

The second resist film R2 formed on the upper layer side of the gate insulating film 33 is exposed through the photomask P having the same exposure pattern as that of the photomask P used to expose the first resist film R1. The amount of exposure of the second resist film R2 varies for each portion overlapping each of the regions A1 to A3 of the photomask P. That is, in the second resist film R2, the portion overlapping the light shielding region A1 is hardly exposed, the portion overlapping the transmissive region A2 is sufficiently exposed, and the portion overlapping the semi-transmissive region A3 is exposed with a smaller amount of light than the portion overlapping the transmissive region A2. The second resist film R2 is made of a positive photosensitive material, and thus, when the second resist film R2 is developed, the exposed portion (the portion overlapping the transmissive region A2) is removed, the unexposed portion (the portion overlapping the light shielding region A1) remains, and the semi-exposed portion (the portion overlapping the semi-transmissive region A3) remains with a film thickness corresponding to the amount of exposure. The gate insulating film 33 is etched using the developed second resist film R2 as a mask, thereby providing the first thick portion 33A located in an area overlapping the transmissive region A2 of the photomask P, and the second thick portion 33B located in an area overlapping the semi-transmissive region A3.

As described above, the photomask P having the same exposure pattern can be used in the step of exposing the first resist film R1 and the step of exposing the second resist film R2, which is suitable for reducing costs associated with the equipment required for manufacturing.

### Second Embodiment

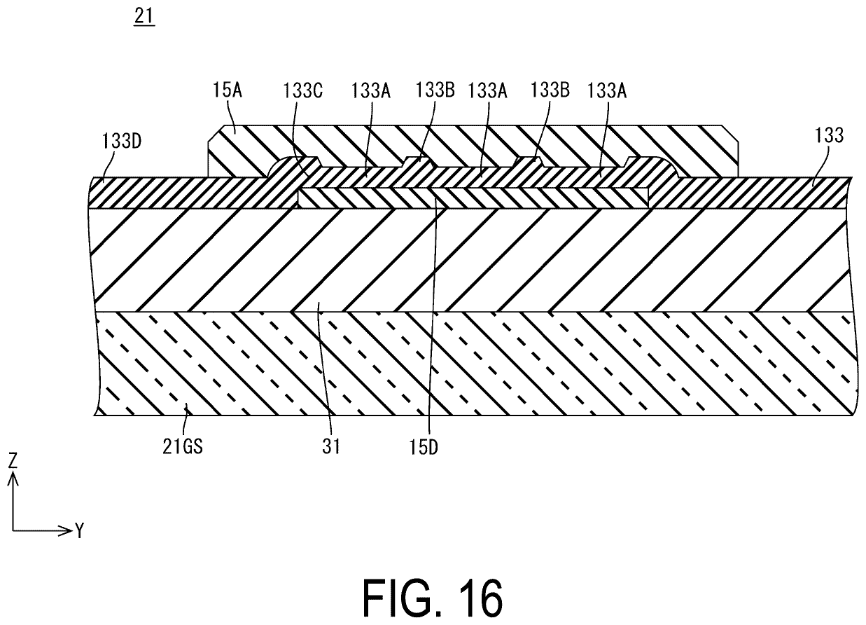

A second embodiment will be described with reference to FIG. 16. In the second embodiment, a case where a configuration of a gate insulating film 133 is changed is described. Further, repetitive descriptions of structures, actions, and effects similar to those of the first embodiment described above will be omitted.

The gate insulating film 133 in this embodiment has a single-layer structure as shown in FIG. 16. The gate insulating film 133 is made of, for example, SiO₂. The gate insulating film 133 has a film thickness that varies depending on a portion, the film thickness being, for example, approximately 100 nm in a first thick portion 133A and being, for example, approximately 150 nm in a second thick portion 133B, a third thick portion 133C, and a fourth thick portion 133D. In order to form such a gate insulating film 133, an etching process time and the like are adjusted in a second etching step of a fourth step, and thus it is possible to control a depth to which a portion that is exposed without being covered by a second resist film R2 (see FIG. 14) is removed.

As described above, according to this embodiment, the gate insulating film 133 has a single-layer structure. Compared to a case where the gate insulating film has a layered structure including a plurality of insulating films, a film formation process required for manufacturing can be reduced.

### Third Embodiment

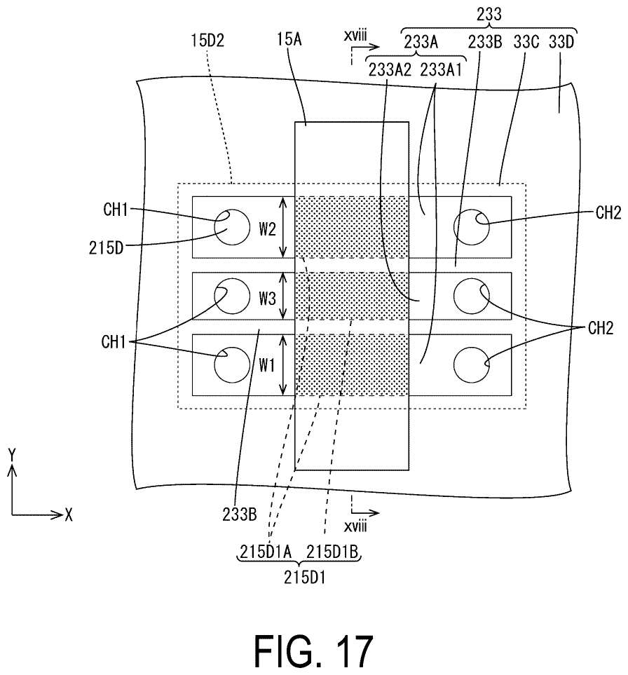

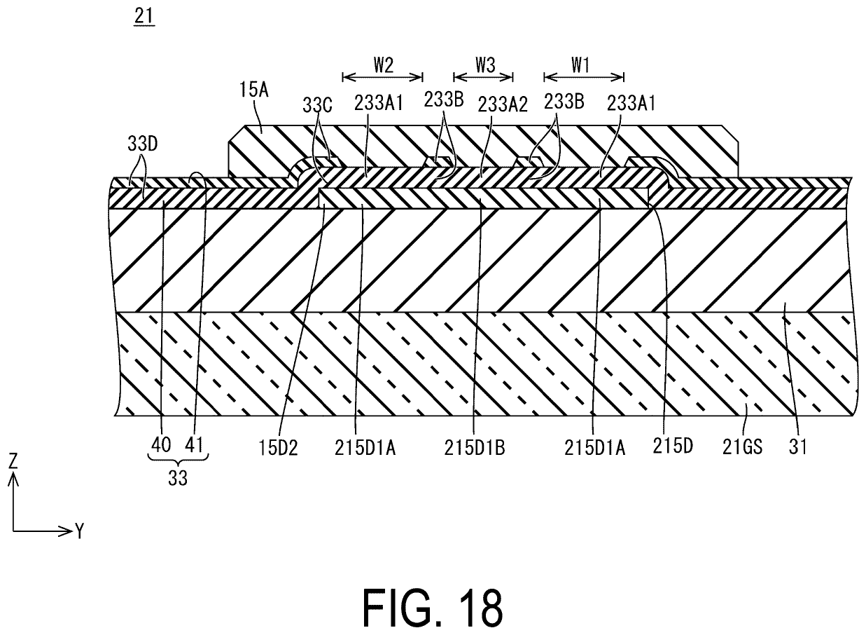

A third embodiment will be described with reference to FIGS. 17 and 18. In the third embodiment, a case where a configuration of a first thick portion 233A is changed from that of the first embodiment described above is described. Further, repetitive descriptions of structures, actions, and effects similar to those of the first embodiment described above will be omitted.

As shown in FIGS. 17 and 18, a gate insulating film 233 of this embodiment is configured such that three first thick portions 233A lined up at intervals in the Y-axis direction have different width dimensions (dimensions in the Y-axis direction (second direction)). In the following, among the three first thick portions 233A, two first thick portions 233A located at both ends in the Y-axis direction are both referred to as an “end-side first thick portion (one first thick portion) 233A1”, and the first thick portion 233A disposed to be interposed between these two end-side first thick portions 233A1 and located in the center (other than both ends) in the Y-axis direction is referred to as a “center-side first thick portion (the other first thick portion) 233A2”. Width dimensions W1 and W2 of the two end-side first thick portions 233A1 are substantially equal to each other. On the other hand, a width dimension W3 of the center-side first thick portion 233A2 is smaller than the width dimensions W1 and W2 of the two end-side first thick portions 233A1.

Here, the center-side portion of the first semiconductor portion 215D in the Y-axis direction dissipates less heat than the end-side portions in the Y-axis direction, and thus heat tends to be accumulated. For this reason, there is a concern that a large temperature difference will occur between the center-side portion and the end-side portion of the first semiconductor portion 215D in the Y-axis direction. In this regard, the width dimension W3 of the center-side first thick portion 233A2 located in the center in the Y-axis direction is smaller than the width dimensions W1 and W2 of the two end-side first thick portions 233A1 located at both ends in the Y-axis direction, and thus a center-side channel region (the other channel region) 215D1B generated in the center-side portion in the Y-axis direction of the first semiconductor portion 215D has a width dimension (dimension in the Y-axis direction (second direction)) smaller than those of the two end-side channel regions (one channel region) 215D1A generated in the both end-side portions in the Y-axis direction. Thus, the amount of current flowing through the center-side channel region 215D1B is smaller than the amount of current flowing through each of the two end-side channel regions 215D1A, and thus self-heating occurring in the center-side channel region 215D1B is also less than self-heating occurring in each of the two end-side channel regions 215D1A. Thereby, it is possible to reduce a temperature difference that may occur between the center-side portion in the Y-axis direction and the end-side portions in the Y-axis direction in the first semiconductor portion 215D.

As described above, according to this embodiment, at least three first thick portions 233A are disposed at intervals in the second direction, at least two second thick portions 233B are arranged at intervals in the second direction, and the first thick portions 233A located at other than both ends in the second direction, among the at least three first thick portions 233A, have dimensions in the second direction which are smaller than those of the two first thick portions 233A located at both ends in the second direction. According to such a configuration, a channel region 215D1 is selectively generated in each of the portions of the first semiconductor portion 215D which overlap the at least three first thick portions 233A. The center-side portion of the first semiconductor portion 215D in the second direction dissipates less heat than the end-side portions in the second direction, and thus heat tends to be accumulated. In this regard, the first thick portions 233A located at other than both ends in the second direction have a dimension in the second direction which is smaller than those of the two first thick portions 233A located at both ends in the second direction, and thus the channel region 215D1 generated in the center-side portion of the first semiconductor portion 215D in the second direction has a dimension in the second direction which is smaller than those of the two channel regions 215D1 generated at both end-side portions in the second direction. Thus, the amount of current flowing through the channel region 215D1 generated in the center-side portion of the first semiconductor portion 215D in the second direction is reduced, and self-heating is reduced. Thereby, it is possible to reduce a temperature difference that may occur between the center-side portion in the second direction and the end-side portions in the second direction in the first semiconductor portion 215D.

### Fourth Embodiment

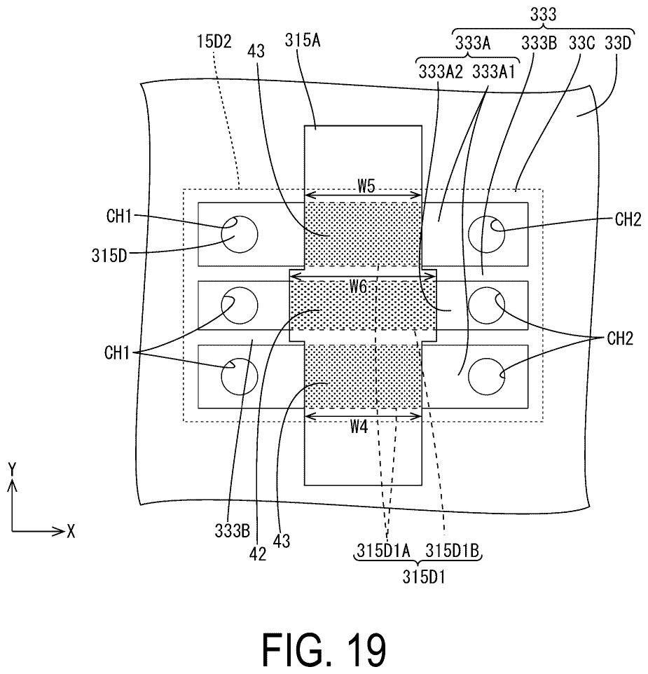

A fourth embodiment will be described with reference to FIG. 19. In the fourth embodiment, a case where a configuration of a first gate electrode 315A is changed from that of the third embodiment described above is described. Further, repetitive descriptions of structures, actions, and effects similar to those of the third embodiment described above will be omitted.

As shown in FIG. 19, the first gate electrode 315A in this embodiment is configured such that its width dimension (dimension in the X-axis direction (first direction)) varies depending on its position in the Y-axis direction. In detail, the first gate electrode 315A includes a first overlapping portion 42 overlapping a center-side first thick portion 333A2 of a gate insulating film 333, and two second overlapping portions 43 overlapping two end-side first thick portions 333A1 of the gate insulating film 333. Among these, width dimensions W4 and W5 of the two second overlapping portions 43 are substantially equal to each other. On the other hand, a width dimension W6 of the first overlapping portion 42 is larger than the width dimensions W4 and W5 of the two second overlapping portions 43.

Here, a center-side portion of the first semiconductor portion 315D in the Y-axis direction dissipates less heat than the end-side portions in the Y-axis direction, and thus heat tends to be accumulated. Thus, there is a concern that a large temperature difference will occur between the center-side portion and the end-side portion of the first semiconductor portion 315D in the Y-axis direction. In this regard, the width dimension W6 of the first overlapping portion 42 overlapping the center-side first thick portion 333A2 of the first gate electrode 315A is larger than the width dimensions W4 and W5 of the two second overlapping portions 43 overlapping the two end-side first thick portions 333A1 of the first gate electrode 315A, and thus a center-side channel region 315D1B generated in the center-side portion in the Y-axis direction in the first semiconductor portion 315D has a length dimension (dimension in the X-axis direction (first direction)) which is larger than those of two end-side channel regions 315D1A generated in the both end-side portions in the Y-axis direction. Thus, the amount of current flowing through the center-side channel region 315D1B is smaller than the amount of current flowing through each of the two end-side channel regions 315D1A, and thus self-heating occurring in the center-side channel region 315D1B is also less than self-heating occurring in each of the two end-side channel regions 315D1A. Thereby, it is possible to reduce a temperature difference that may occur between the center-side portion in the Y-axis direction and the end-side portions in the Y-axis direction in the first semiconductor portion 315D.

As described above, according to this embodiment, at least three first thick portions 333A are disposed at intervals in the second direction, at least two second thick portions 333B are disposed at intervals in the second direction, and the first gate electrode 315A includes a first overlapping portion 42 which overlaps the first thick portions 333A located at other than both ends in the second direction among the at least three first thick portions 333A, and two second overlapping portions 43 that overlap the two first thick portions 333A located at both ends in the second direction among the at least three first thick portions 333A, and the first overlapping portion 42 has a dimension in the first direction which is larger than that of the second overlapping portion 43. According to such a configuration, the channel region 315D1 is selectively generated in each of the portions of the first semiconductor portion 315D which overlap the at least three first thick portions 333A. The center-side portion of the first semiconductor portion 315D in the second direction dissipates less heat than the end-side portions in the second direction, and thus heat tends to be accumulated. In this regard, the first overlapping portion 42 of the first gate electrode 315A has a dimension in the first direction which is larger than that of the second overlapping portion 43, and thus the channel region 315D1 generated in the center-side portion of the first semiconductor portion 315D in the second direction has a dimension in the first direction which is larger than those of the two channel regions 315D1 generated at both end-side portions in the second direction. Thus, the amount of current flowing through the channel region 315D1 generated in the center-side portion of the first semiconductor portion 315D in the second direction is reduced, and self-heating is reduced. Thereby, it is possible to reduce a temperature difference that may occur between the center-side portion in the second direction and the end-side portions in the second direction in the first semiconductor portion 315D.

### Other Embodiments

The technology described in the present specification is not limited to the embodiments described above and shown in the drawings, and the following embodiments, for example, are also included within the technical scope.

(1) The formation ranges for the first thick portions 33A, 133A, 233A, and 333A in a plan view can be changed as appropriate to areas other than those shown in the drawings. For example, the formation ranges for the first thick portions 33A, 133A, 233A, and 333A may be limited to areas which overlap the first gate electrodes 15A and 315A.

(2) In the configurations described in the first, third and fourth embodiments, the first thick portion 33A, 233A, and 333A may partially include the upper insulating film 41 in addition to the lower insulating film 40. That is, when etching is performed in the fourth step, an upper layer portion of the upper insulating film 41 may be removed, and a lower layer portion of the upper insulating film 41 may be left.

(3) Regarding each of the first thick portions 33A, 133A, 233A, and 333A, two or four or more first thick portions may be provided lined up at intervals in the Y-axis direction.

(4) In (3) described above, when the configuration in which four or more first thick portions of each of the first thick portions 33A, 133A, 233A, and 333A are lined up is applied to the configuration described in the third and fourth embodiments, a configuration in which a plurality of center-side first thick portions of each of the center-side first thick portions 233A2 and 333A2 are provided is obtained. In this case, the width dimension of each of the plurality of center-side first thick portions 233A2 and 333A2 may be made smaller than the width dimension of each of the end-side first thick portions 233A1 and 333A1. Furthermore, when there are three or more center-side first thick portions of each of the first thick portions 233A2 and 333A2, it is also possible to make the width dimension 233A2 and 333A2 located on the center side smaller than the width dimension of each of the center-side first thick portions 233A2 and 333A2 located on the end side for the three or more center-side first thick portions 233A2 and 333A2.

(5) In (3) described above, when the configuration in which four or more first thick portions of each of the first thick portions 33A, 133A, 233A, and 333A are lined up is applied to the configuration described in the fourth embodiment, a configuration in which a plurality of first overlapping portions 42 are provided in the first gate electrode 315A is obtained. In this case, the width dimension of each of the plurality of first overlapping portions 42 may be made larger than the width dimension of the second overlapping portion 43. Furthermore, when there are three or more first overlapping portions 42, it is also possible to make the width dimension of the first overlapping portion 42 located on the center side larger than the width dimension of the first overlapping portion 42 located on the end side for the three or more first overlapping portions 42.

(6) The configuration described in the third embodiment may be combined with the configuration described in the second embodiment.

(7) The configuration described in the fourth embodiment may be combined with the configurations described in the first and second embodiments.

(8) Specific materials used for the films on the array substrate 21 and specific numerical values of film thicknesses of the films can be changed as appropriate to those not mentioned above.

(9) The first gate electrodes 15A and 315A may be configured to intersect the first semiconductor portions 15D, 215D and 315D at an angle other than 90°.

(10) Specific planar shapes of the first gate electrodes 15A and 315A and the first semiconductor portions 15D, 215D, and 315D can be changed as appropriate to those not shown in the drawings. When the first semiconductor portions 15D, 215D, and 315D include a portion extending in the X-axis direction, it may be bent midway. When the first gate electrodes 15A and 315A include a portion extending in the Y-axis direction, it may be bent midway.

(11) In each of the exposure steps included in the third and fourth steps, a gray-tone mask may be used as the photomask P in addition to the half-tone mask.

(12) It is also possible to make the exposure pattern of the photomask P used in the third step different from that of the photomask P used in the fourth step.

(13) Instead of the driver 12, a source shared driving (SSD) circuit or the like may be monolithically provided on the array substrate 21. In this case, circuit elements of the SSD circuit may also include the first TFT 15.

(14) The driver 12 may be attached to the flexible substrate 13.

(15) Instead of the circuit portion 14, a gate driver may be attached to the array substrate 21.

(16) It is also possible to reverse the order of layering the semiconductor film 32 and the second metal film. That is, in the first TFT 15, the gate insulating films 33, 133, 233, and 333 may be located on the upper layer sides of the first gate electrode 15A and 315A constituted of the second metal film, and the first semiconductor portions 15D, 215D, and 315D constituted of the semiconductor film 32 may be located on the upper layer sides of the gate insulating films 33, 133, 233, and 333. In this case, the first TFT 15 is a bottom gate type. The semiconductor film 32 may also be constituted of an amorphous silicon thin film or an oxide semiconductor thin film. The second TFT 24 is also a bottom gate type.

(17) The first TFT 15 and the second TFT 24 may be of a double gate type or the like other than a top gate type or a bottom gate type.

(18) In the pixel electrode 25 and the common electrode 28, an “upper electrode” which is an electrode located on the upper layer side may be the common electrode 28, and a “lower electrode” which is an electrode located on the lower layer side may be the pixel electrode 25. In this case, a slit is provided in the common electrode 28 which is the “upper electrode”.

(19) The touch panel pattern may be a mutual capacitance type other than a self-capacitance type.

(20) The liquid crystal panel 11 may not have a touch panel pattern (touch panel function). In this case, the common electrode 28 has a non-divided structure, the touch electrode 29 is not formed, and the touch wiring line 30 (third metal film) is not formed.

(21) The color filter 29 may be provided on the array substrate 21. That is, the liquid crystal panel 11 may have a color filter on array (COA) structure.

(22) The number of colors of the color filter 29 may be four or more. The color filter 29 to be added may be a yellow color filter exhibiting yellow, a transparent color filter transmitting light of a full wavelength region, or the like.

(23) A display mode of the liquid crystal panel 11 may be a VA mode, an IPS mode, or the like other than an FFS mode.

(24) The liquid crystal panel 11 may be a reflective type or a semi-transmissive type other than a transmissive type. When the liquid crystal panel 11 is a reflective type, the backlight device can be omitted.

(25) A display panel other than the liquid crystal panel 11 (such as an organic EL display panel) may be used.

(26) In addition to the head mounted display (HMD) 10, the present disclosure can also be applied to devices such as head-up displays and projectors that use lenses or the like to enlarge and display an image displayed on the liquid crystal panel 11. The present disclosure can be also applied to a display device that does not have an enlarged display function (a television receiver, a tablet terminal, a smartphone, or the like).

While preferred embodiments of the present invention have been described above, it is to be understood that variations and modifications will be apparent to those skilled in the art without departing from the scope and spirit of the present invention. The scope of the present invention, Thus, is to be determined solely by the following claims.

1. A transistor comprising:
a semiconductor portion extending in a first direction, the semiconductor portion being made of a semiconductor material;
a first electrode extending in a second direction intersecting the first direction, the first electrode being disposed overlapping a portion of the semiconductor portion;
a first insulating film interposed between the first electrode and the semiconductor portion;
a second electrode disposed overlapping a portion of the semiconductor portion, the second electrode being connected to the semiconductor portion; and
a third electrode disposed overlapping a portion of the semiconductor portion at a position spaced apart from a connection position between the second electrode and the semiconductor portion in the first direction, the third electrode being connected to the semiconductor portion,
wherein the first insulating film includes a first thick portion and a second thick portion having a film thickness greater than a thickness of the first thick portion,
at least two of the first thick portions are disposed at intervals in the second direction at positions overlapping both the first electrode and the semiconductor portion, and
the second thick portion is disposed to be interposed between the two first thick portions in the second direction at a position overlapping both the first electrode and the semiconductor portion.

2. The transistor according to claim 1,
wherein the first insulating film has a layered structure of a lower insulating film disposed on an upper layer side of the semiconductor portion and an upper insulating film disposed on an upper layer side of the lower insulating film and made of a material different from a material of the lower insulating film.

3. The transistor according to claim 2,
wherein the first thick portion is constituted of the lower insulating film, and the second thick portion is constituted of the upper insulating film and the lower insulating film.

4. The transistor according to claim 1,
wherein the first insulating film has a single-layer structure.

5. The transistor according to claim 1,
wherein the first insulating film includes a third thick portion having a film thickness greater than a thickness of the first thick portion, and
the third thick portion is disposed overlapping an outer peripheral end of the semiconductor portion.

6. The transistor according to claim 5,
wherein the third thick portion has the same film thickness as that of the second thick portion.

7. The transistor according to claim 1,
wherein at least three of the first thick portions are disposed at intervals in the second direction,
at least two of the second thick portions are disposed at intervals in the second direction, and
among the at least three first thick portions, the first thick portion located at other than both ends in the second direction has a dimension in the second direction which is smaller than a dimension of the two first thick portions located at the both ends in the second direction.

8. The transistor according to claim 1,
wherein at least three of the first thick portions are disposed at intervals in the second direction,
at least two of the second thick portions are disposed at intervals in the second direction,
the first electrode includes a first overlapping portion that overlaps the first thick portion located at other than both ends in the second direction among the at least three first thick portions, and two second overlapping portions that overlap the two first thick portions located at the both ends in the second direction among the at least three first thick portions, and
the first overlapping portion has a dimension which is larger in the first direction than a dimension of the second overlapping portion.

9. A manufacturing method for a transistor, the manufacturing method comprising:
forming a semiconductor film made of a semiconductor material;
forming a first resist film made of a photosensitive material on an upper layer side of the semiconductor film;
exposing and developing the first resist film;
providing a semiconductor portion extending in a first direction by etching the semiconductor film using the first resist film as a mask;
forming a first insulating film on an upper layer side of the semiconductor portion;
forming a second resist film made of a photosensitive material on an upper layer side of the first insulating film;
exposing and developing the second resist film;
etching the first insulating film using the second resist film as a mask to provide at least two first thick portions disposed at intervals in a second direction intersecting the first direction so as to overlap the semiconductor portion, and a second thick portion that is disposed to be interposed between the two first thick portions in the second direction at positions overlapping the semiconductor portion and has a film thickness greater than a thickness of the first thick portion;
forming a first conductive film on an upper layer side of the first insulating film and patterning the first conductive film to provide a first electrode that extends in the second direction, overlaps a portion of the semiconductor portion, and is disposed to overlap the at least two first thick portions and the second thick portion; and
forming a second conductive film on an upper layer side of the first electrode and patterning the second conductive film to provide a second electrode that is disposed to overlap a portion of the semiconductor portion and is connected to the semiconductor portion, and a third electrode that is disposed to overlap a portion of the semiconductor portion at a position spaced apart from a connection position between the second electrode and the semiconductor portion in the first direction and is connected to the semiconductor portion.

10. The manufacturing method for the transistor according to claim 9, further comprising:
forming the first resist film made of a negative photosensitive material on the upper layer side of the semiconductor film,
exposing the first resist film through a photomask and then developing the first resist film, the photomask having a light shielding region disposed not to overlap a formation area for the semiconductor portion to be formed to block light, at least two transmissive regions disposed at intervals in the second direction so as to overlap the formation area for the semiconductor portion to be formed, the transmissive regions transmitting light, and a semi-transmissive region overlapping the formation area for the semiconductor portion to be formed, disposed to be interposed between the at least two transmissive regions in the second direction, and having a light transmittance higher than a light transmittance of the light shielding region and lower than a light transmittance of the transmissive region,
forming the second resist film made of a positive photosensitive material on the upper layer side of the first insulating film, and
exposing the second resist film through the photomask and then developing the second resist film.
